(19) United States
(12) Patent Application Publication
(10) Pub. No.: US 2025/0070756 A1
(43) Pub. Date: Feb. 27, 2025

(54) CONTINUOUSLY VARIABLE ACTIVE REACTANCE SYSTEMS AND METHODS

(71) Applicant: Etherdyne Technologies, Inc., Santa Clara, CA (US)

(72) Inventor: Robert A. Moffatt, Palo Alto, CA (US)

(21) Appl. No.: 18/943,080

(22) Filed: Nov. 11, 2024

Related U.S. Application Data
(63) Continuation of application No. 18/043,111, filed on Feb. 27, 2023, now Pat. No. 12,143,083.
(60) Provisional application No. 63/071,048, filed on Aug. 27, 2020.

(51) Int. Cl. H03H 11/02; H02J 50/12

(52) U.S. Cl. CPC H03H 11/02; H02J 50/12

(57) ABSTRACT

Various embodiments for controlling a resonant frequency of a resonator are described. A system includes at least one resonant circuit and an active variable reactance circuit that controls a resonant frequency of the at least one resonant circuit. The active variable reactance circuit includes an electrically-controllable switching element and a switch controller sub-circuit configured to switch the electrically-controllable switching element at a frequency of a radio-frequency (RF) current or voltage passing through or across a device such that the RF current flowing from a first terminal to a second terminal is substantially sinusoidal.

### CROSS-REFERENCE TO RELATED APPLICATION

This application is a continuation of U.S. patent application Ser. No. 18/043,111 filed Feb. 27, 2023, now issued as U.S. Pat. No. 12,143,083, which is a national phase application under 35 U.S.C. 371 of International Application No. PCT/US2021/047734 filed Aug. 26, 2021, which claims the benefit of and priority to U.S. Provisional Patent Application No. 63/071,048 entitled “CONTINUOUSLY VARIABLE ACTIVE REACTANCE SYSTEMS AND METHODS,” filed Aug. 27, 2020, the contents of all of which being incorporated by reference in their entireties herein.

### BACKGROUND

Resonant wireless power systems make use of magnetic or electric coupling between LC resonators in order to transfer electric power. The efficiency of such systems is dependent on the quality factors of the resonators, with higher quality factors resulting in higher wireless power transfer efficiency. However, resonators with higher quality factor have a narrower resonant response curve, meaning the driving frequency must be closer to the resonant frequency of the resonators in order for the potential efficiency gains afforded by higher quality factor to be fully realized. Therefore, in systems where the driving frequency is fixed and/or where two or more resonators are present, precise control over the resonant frequencies of all the resonators is essential for optimizing system performance.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1A is an example of a simplified schematic of an LC resonator with an electrically-controlled variable capacitance according to various embodiments of the present disclosure.

FIG. 1B is another example of a simplified schematic of an LC resonator with an electrically-controlled variable inductance according to various embodiments of the present disclosure.

FIG. 2A is an example of a simplified circuit diagram for providing an active variable capacitance according to various embodiments of the present disclosure.

FIG. 2B is a simulate ideal waveform diagram of the simplified circuit diagram of FIG. 2A according to various embodiments of the present disclosure.

FIG. 3A is an example of a simplified circuit diagram for providing an active variable capacitance according to various embodiments of the present disclosure.

FIG. 3B is a simulate ideal waveform diagram of the simplified circuit diagram of FIG. 3A according to various embodiments of the present disclosure.

FIG. 4A is a chart showing an effective capacitive reactance versus duty cycle according to various embodiments of the present disclosure.

FIG. 4B is a chart showing an effective inductive susceptance versus duty cycle according to various embodiments of the present disclosure.

FIG. 5 is a photograph of a printed circuit board (PCB) implementing an active variable capacitance circuit used for collecting measurements shown in FIGS. 6 and 7 according to various embodiments of the present disclosure.

FIG. 6 is a chart showing measured waveforms of the active variable capacitance of the circuit of FIG. 5 according to various embodiments of the present disclosure.

FIG. 7 is a chart showing a measured resonant frequency versus a duty cycle of a resonator containing the active variable capacitance circuit of FIG. 5 according to various embodiments of the present disclosure.

FIG. 8 is an example of a simplified schematic of autotuning repeater resonator according to various embodiments of the present disclosure.

FIG. 9 is a photograph of an autotuning repeater resonator and a directly-driven resonator according to various embodiments of the present disclosure.

FIG. 10 is a schematic block diagram of a system for active variable capacitive reactance according to various embodiments of the present disclosure.

FIG. 11 is a schematic block diagram of a system for active variable inductive reactance according to various embodiments of the present disclosure.

FIG. 12 is a chart showing simulated results of ideal voltage and current waveforms of the active variable capacitance.

FIG. 13 is a graph showing an effective capacitive reactance as a function of duty cycle.

FIG. 14 is a graph showing simulation of ideal voltage and current waveforms of the active variable inductance.

FIG. 15 is a graph showing effective inductive susceptance as a function of duty cycle.

FIG. 16 is a schematic block diagram of a circuit for automatically regulating RF current amplitude of an externally-driven LC resonator using tuning control by way of an active variable reactance according to various embodiments of the present disclosure.

FIG. 17 is a schematic block diagram of a circuit for automatic RF current regulation of an LC resonator by way of an active variable capacitance according to various embodiments of the present disclosure.

FIG. 18 is a Class-E RF generator with automatic zero-voltage switching according to various embodiments of the present disclosure.

FIG. 19 is a chart showing measured gate and drain voltage waveforms for a Class-E amplifier with automatic zero-voltage switching for various loading conditions according to various embodiments of the present disclosure.

FIG. 20 is a chart showing measured gate and drain voltage waveforms for a Class-E amplifier with automatic zero-voltage switching for various tuning conditions according to various embodiments of the present disclosure.

FIG. 21 is a chart showing a measured duty cycle of the AZVS amplifier as a function of resonant frequency of a tank circuit according to various embodiments of the present disclosure.

FIG. 22 is a schematic diagram of a Class-E RF generator with AZVS and autotuning according to various embodiments of the present disclosure.

FIG. 23 is a schematic diagram of a Class-E RF generator that achieves ZVS via tuning using a variable reactance in series with an LC tank circuit according to various embodiments of the present disclosure.

FIG. 24 is a schematic diagram of a Class-E amplifier rearranged so that the RF generator draws direct current (DC) power from the same two terminals it uses to output RF power according to various embodiments of the present disclosure.

FIG. 25 is a simplified schematic diagram of a resonant magnetic loop antenna driven by distributed RF generators according to various embodiments of the present disclosure.

FIG. 26 is a schematic block diagram of an RF Generator for use as part of a distributed RF generator system with AZVS and autotuning according to various embodiments of the present disclosure.

### DETAILED DESCRIPTION

The present disclosure relates to systems and methods for continuously variable active reactance. As noted above, in systems where the driving frequency is fixed and/or where two or more resonators are present, precise control over the resonant frequencies of all the resonators is essential for optimizing system performance. Detuning of the resonators may be caused by a variety of factors, such as variation in component values or interactions with the environment. For this reason, it is desirable to have a way of controlling the resonant frequency of a resonator to correct tuning errors.

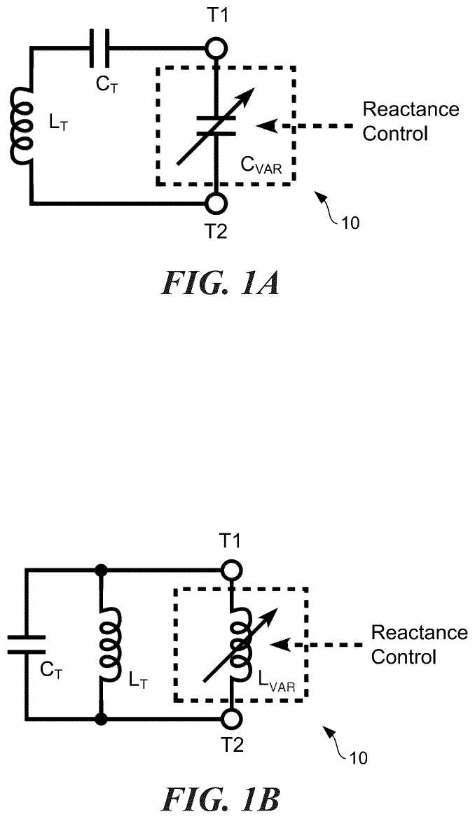

Referring now to the drawings, FIGS. 1A and 1B show two example embodiments for controlling resonant frequency of an LC resonator. In both examples, a resonant LC tank circuit 10 comprises an inductor L_{T} and a capacitor C_{T}. Referring to FIG. 1A, a variable capacitance C_{VAR} is in series with C_{T}, which allows the total series capacitance of the LC resonator to be varied. The resonant frequency of the resonator in FIG. 1A is given by the equation:

$${f}_{r e s} = \frac{1}{2 π \sqrt{{L}_{T} {C}_{s e r i e s}}} , \qquad ( eq . l )$$

where the total series capacitance, Cₛₑᵣᵢₑₛ, is given by:

$${C}_{s e r i e s} = \frac{1}{\frac{1}{{C}_{T}} + \frac{1}{{C}_{V A R}}} . \qquad ( eq . 2 )$$

In FIG. 1B, a variable inductance L_{VAR} is in parallel with L_{T}, which allows the total parallel inductance of the LC resonator to be varied. The resonant frequency of the resonator in FIG. 1B is given by the equation:

$${f}_{r e s} = \frac{1}{2 π \sqrt{{L}_{parallel} {C}_{T}}} , \qquad ( eq . 3 )$$

where the total parallel inductance, Lₚₐᵣₐₗₗₑₗ, is given by:

$${L}_{parallel} = \frac{1}{\frac{1}{{L}_{T}} + \frac{1}{{L}_{V A R}}} . \qquad ( eq . 4 )$$

In order for the LC resonators shown in FIGS. 1A and 1B to be able to respond to changes in their environment without human control, the variable reactance elements may be electrically-controllable. Electrically-controllable reactances can be made using electromechanical systems, non-linear devices, or discretely switched arrays of inductors or capacitors. However, these approaches all have disadvantages for wireless power applications. Electromechanical systems and discretely switched reactance arrays have high cost and complexity, while non-linear devices require DC control voltages and currents which are much larger than the RF voltage and current amplitudes in the LC tank circuit 10, which is often an impractical requirement for high-power systems. It can be therefore desirable to find a means of constructing an electrically-controllable reactive element which does not require an electro-mechanical device or a non-linear reactance, and which can achieve a continuous tuning range using a minimal number of switching devices and minimal complexity.

One way of achieving electrical control including using an electrical motor to adjust the tuning of a variable capacitor or inductor. However, these electro-mechanical solutions are often bulky and complex. Another possible way to achieve electrical control would include using a non-linear reactive element, such as a varactor or a saturable ferrite. However, these non-linear devices require DC control voltages or currents much larger than the amplitude of the RF current or voltage passing through or across the device in order to behave as a variable reactance. This condition is easy to satisfy when the LC resonator is being used to resonate with weak signals, such as in a radio receiver tank circuit. However, this condition is often difficult or impossible to satisfy when the LC resonator is part of a high-power wireless power system in which the amplitudes of the RF voltages and currents in the resonator are already fairly large. Another way, which maintains linearity, but which does not require electro-mechanical components, is to use electrically-controlled switches, such as metal-oxide-semiconductor field-effect transistor (MOSFETs), bipolar junction transistors (BJTs), relays, etc., to switch reactive components in and out of the LC resonator.

Each state of the switches provides a single tuning state. Therefore, the number of possible states will be equal to two raised to the number of switches. However, this approach has various disadvantages. First, only certain, discrete tuning frequencies are achievable. It is not possible to tune over a continuous range. Second, the system requires more switches and, therefore, becomes more complex as more tuning states are added. Third, the system requires digital control which also adds to its complexity. Therefore, it is desirable to provide an electrically-controllable reactive element which does not require an electro-mechanical device or a non-linear reactance that can achieve a continuous tuning range using a minimal number of switching devices and minimal complexity.

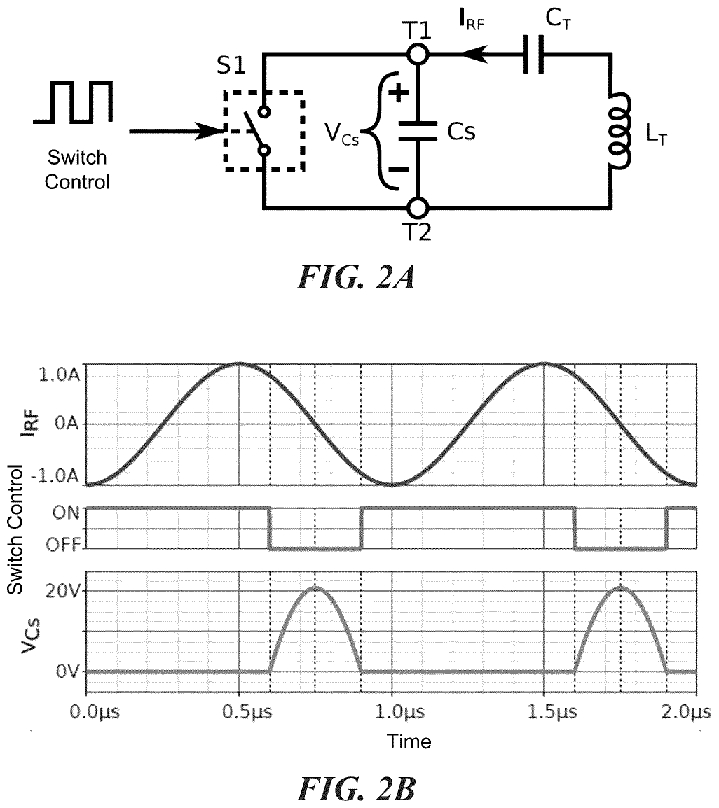

The desirable attributes described above may be achieved with active variable reactance. Accordingly, FIGS. 2A and 2B show example circuits where active variable reactances may be constructed using a single electrically-controllable switching device S1 switched on and off at the frequency of the sinusoidal RF current or voltage in the LC tank circuit 10. The LC tank circuit 10 may be powered indirectly through inductive or capacitive coupling to an external RF source with a drive frequency fd, for example.

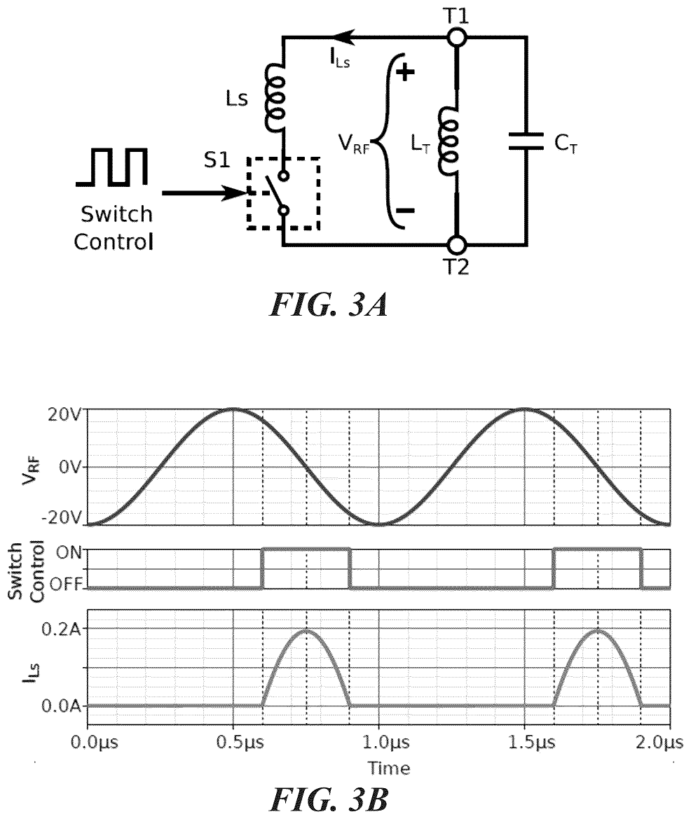

The tuning of the resonators shown in FIGS. 2A and 3A may be adjusted by changing the duty cycle of the switch. Using this single, electrically-controlled switching device, these circuits can produce variable reactance without the complexity of the electromechanical systems or switched arrays and without the need for the large DC voltages or currents required by the non-linear systems.

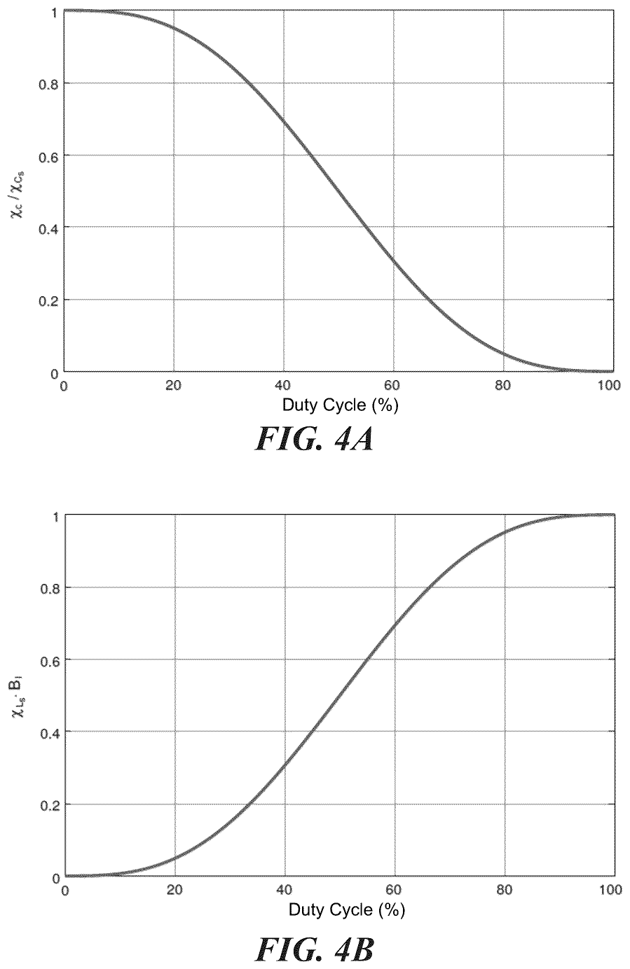

In the active variable capacitance shown in FIG. 2A, the LC tank circuit 10 ensures that the RF current/RF, flowing from terminal T₁ to terminal T₂, is nearly sinusoidal. This RF current/RF is shown in the top plot of FIG. 2B. The middle plot shows the switch control square wave. The phase of the square wave is chosen such that the negative-slope zero-crossing of RF current/RF occurs at the midpoint of the low period. The bottom plot shows the voltage V_{Cs}, across capacitor Cₛ, where it is assumed that Cₛ>>C_{T}. When the switch is off, the capacitor Cₛ, is first charged and then discharged by the current I_{RF}. The phase relation between I_{RF} and the Switch Control square wave guarantees zero-voltage switching, ensuring that the switch does not dissipate energy by discharging Cₛ when it turns on. The voltage waveform, V_{Cs}(t) contains many harmonics. However, the LC tank circuit 10 acts as a filter which responds primarily to the fundamental. Therefore, an effective reactance x_{c} may be defined by dividing the amplitude of this fundamental by the amplitude of the RF current:

$${x}_{c} = {x}_{{C}_{s}} ( \frac{sin ( 2 π d )}{2 π} - δ + 1 ) , \qquad ( eq . 5 )$$

where x_{C}_{ₛ}≡1/(ωCₛ) is the reactance of capacitor Cₛ at the angular frequency ω of the RF current. Eq. 5 shows that the effective reactance may be continually varied by changing the switch duty cycle δ. The relation between the duty cycle and the effective capacitive reactance is plotted in FIG. 4A. This reactance is equivalent to the following effective variable capacitance:

$${C}_{V A R} = \frac{1}{ω {x}_{c}} = \frac{{C}_{s}}{\frac{sin ( 2 πδ )}{2 π} - δ + 1} . \qquad ( eq . 6 )$$

In the active variable inductance shown in FIG. 3A, the LC tank circuit 10 ensures that the RF voltage V_{RF} between terminal T₁ and terminal T₂ is nearly sinusoidal. This RF voltage is shown in the top plot of FIG. 3B. The middle plot shows the switch control square wave. The phase of the square wave is chosen such that the negative-slope zero-crossing of RF voltage V_{RF} occurs at the midpoint of the high period. The bottom plot shows the current, I_{Ls}, through inductor Lₛ, where it is assumed that Lₛ>>L_{T}. When the switch is on, the voltage V_{RF} causes the inductor current to first rise and then fall. The phase relation between V_{RF} and the switch control square wave guarantees zero-current switching, ensuring that the switch does not dissipate energy. The current waveform I_{Ls}(t), contains many harmonics. However, the LC tank circuit 10 acts as a filter which responds primarily to the fundamental. Therefore, an effective susceptance Bₗ may be defined by dividing the amplitude of this fundamental by the amplitude of the RF voltage:

$${B}_{l} = \frac{1}{x {L}_{s}} ( δ - \frac{sin ( 2 π d )}{2 π} ) , \qquad ( eq . 7 )$$

where xLₛ≡wLₛ is the reactance of inductor Lₛ at the angular frequency ω of the RF voltage. Eq. 7 shows that the effective susceptance may be continually varied by changing the switch duty cycle δ. The relation between the duty cycle and the effective inductive susceptance is plotted in FIG. 4B. The effective inductive reactance is equal to the reciprocal of the effective inductive susceptance:

$$X l = \frac{1}{{B}_{l}} = \frac{x {L}_{s}}{δ - \frac{sin ( 2 π d )}{2 π}} . \qquad ( eq . 8 )$$

This reactance is equivalent to the following effective variable inductance:

$${L}_{V A R} = \frac{X l}{ω} = \frac{{L}_{s}}{δ - \frac{sin ( 2 π d )}{2 π}} . \qquad ( eq . 9 )$$

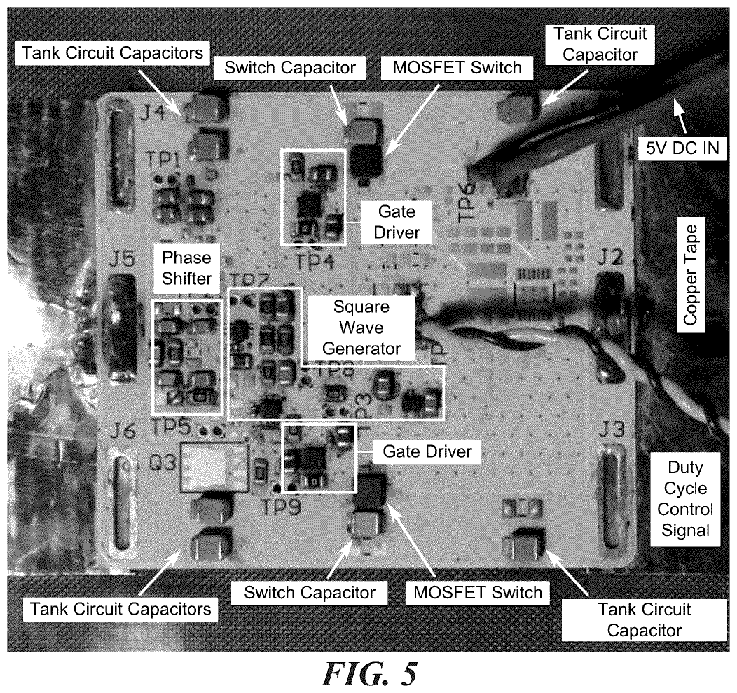

FIG. 5 shows an active variable capacitance circuit that was soldered to an inductive loop made from copper tape, although other materials may be employed. The loop was inductively driven by an external RF source. The switch was implemented with a parallel pair of MOSFETs. To generate the gate-drive signal, the sinusoidal voltage across a capacitor in series with the loop was sent through a phase shift network and into a comparator to generate a square wave, which was then converted into a triangle wave by an RC filter and fed into a second comparator to produce a square wave with controllable duty cycle.

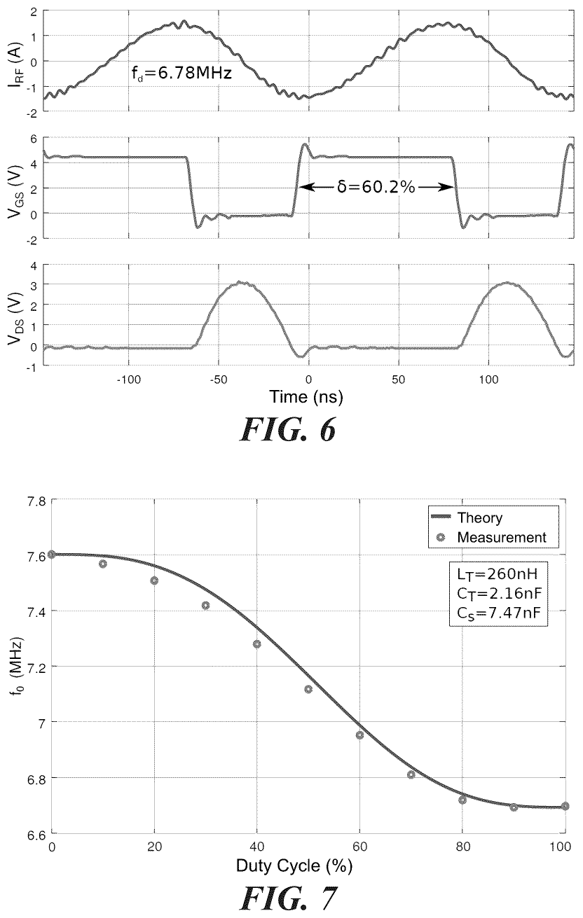

FIG. 6 shows measurements of the gate, drain, and RF current waveforms, which are in good agreement with the shapes of the ideal waveforms shown in FIG. 2B. More specifically, in FIG. 5, measured waveforms of the active variable capacitance circuit in FIG. 5 are shown. Current/RF was determined from the time derivative of the voltage across a series capacitor. A 200 MHz low-pass filter was applied in software to remove high-frequency noise amplified by the derivative.

To test the validity of eq. 6, the resonator was inductively coupled to a driven loop. The gate-drive duty cycle was varied, and for each value of the duty cycle, the resonant frequency was measured by finding the drive frequency at which the RF current in the resonator was maximized. The results are plotted in FIG. 7 and show fairly good agreement with the prediction of eq. 6. Specifically, FIG. 7 shows a measured resonant frequency versus a duty cycle of a resonator containing the active variable capacitance circuit shown in FIG. 5.

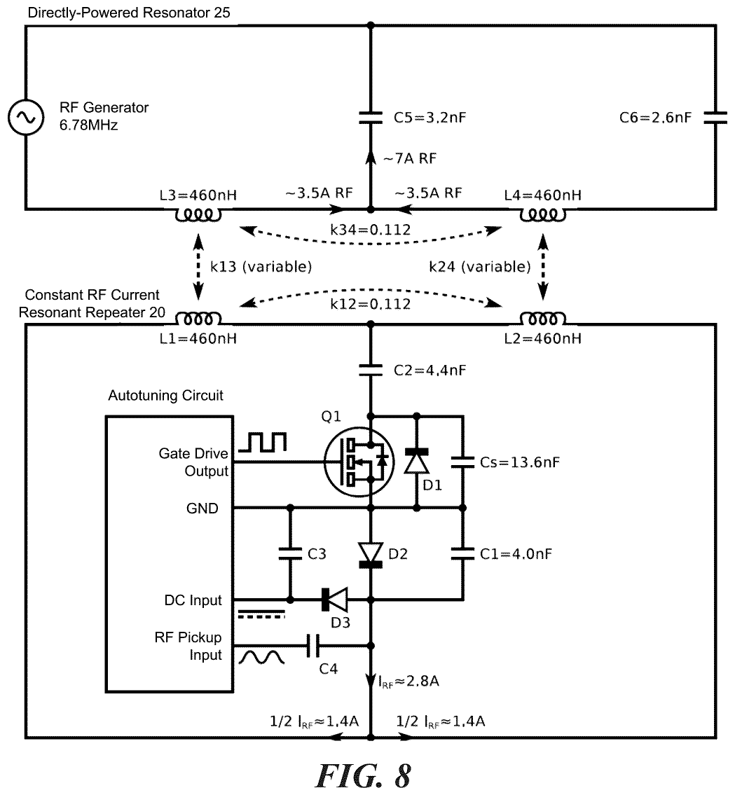

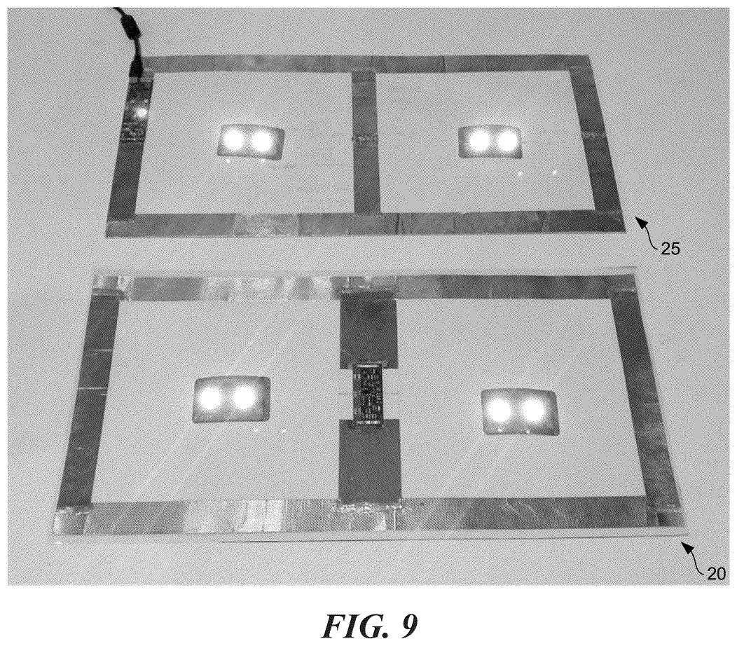

The ability to electrically control the tuning of an LC resonator has many uses in resonant wireless power transfer. One example is the system shown in FIG. 8 in which an active variable capacitance is used in combination with a feedback circuit to maintain a constant RF current amplitude in a wireless repeater resonator. A constant RF current resonant repeater 20 (e.g., the lower resonator in the schematic of FIG. 8 and the photograph of FIG. 9) is inductively coupled to a directly-powered resonator 25 (upper resonator in the schematic of FIG. 8 and the photograph of FIG. 9), driven at 6.78 MHz. Each resonator measures approximately 25 cm×50 cm. The resonant repeater 20 automatically adjusts its tuning to maintain a constant RF current amplitude I_{RF}. The direct and repeater resonators are each powering two regulated wireless 360 mW LED loads (e.g., the LED lights shown in FIG. 9). Note that inductors L₁ and L₂ have equal current amplitude, with opposite directions of circulation. In the directly-powered resonator, the capacitors C₅ and C₆ are chosen such that L₃ and L₄ also have equal RF current amplitude, with opposite directions of circulation.

The capacitors Cs, C1, and C2 can be selected such that, for any duty cycle of the active variable capacitance, the resonant frequency of the repeater resonator is always higher than the drive frequency produced by an RF Generator. This implies that the RF current amplitude is a monotonic function of the duty cycle. The autotuning circuit measures the rectified DC voltage across C₃, which is proportional to the RF current amplitude I_{RF} in the resonant repeater 20. A feedback loop may be provided that regulates the duty cycle of the gate-drive square wave in order to keep this rectified DC voltage constant. As a result, this feedback loop automatically changes the tuning of the repeater resonator such that the RF current amplitude/RF remains constant, even as the inductive coupling k13 and k24 is changed by moving the repeater resonator relative to the directly-powered resonator. The system shown in FIG. 8 was able to keep the RF current amplitude in the repeater resonator within ±1% of 2.83 A as the separation between the direct and repeater resonators was varied from 2.0 cm to 5.5 cm.

The active variable capacitance and active variable inductance circuits shown in FIGS. 2A and 3A, respectively, allow the resonant frequency of an LC resonator to be electrically controlled over a continuous range, at high RF power levels, with low cost and complexity, using a single switching device. The electrical control of resonance has many uses in resonant wireless power transfer. One example shown herein includes the automatic regulation of the RF current amplitude in a repeater resonator via a feedback loop controlling an active variable capacitance. Other potential applications include making wireless transmitters or receivers less sensitive to component variations, or environmental perturbations.

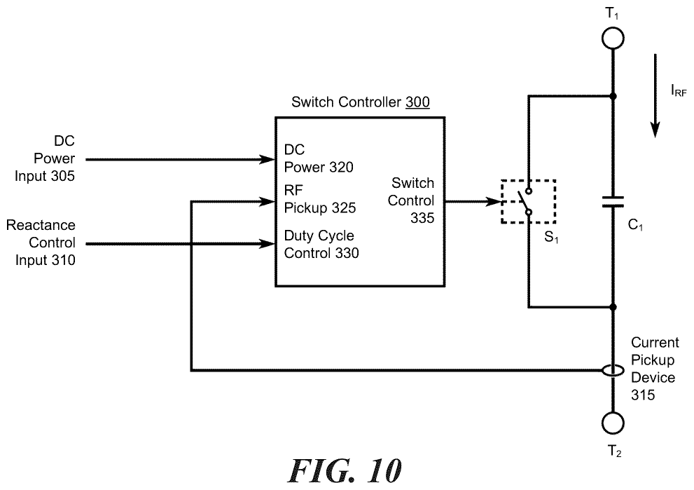

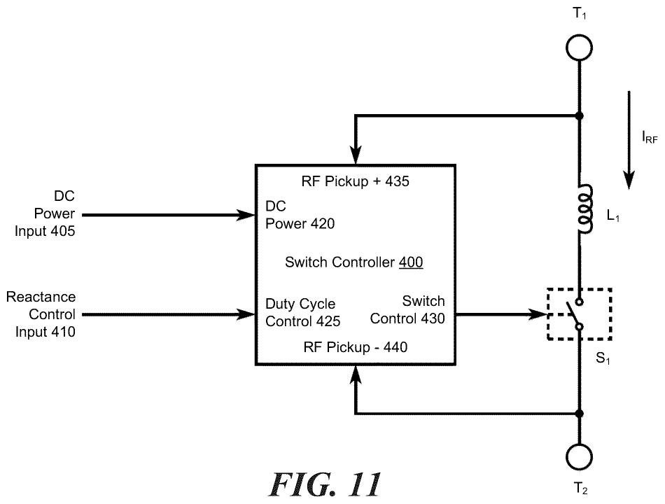

FIGS. 10 and 11 show example embodiments for how electrically-controllable linear variable reactances may be constructed using an electrically-controllable switching element S₁ that is switched on and off at the frequency of the RF current or voltage passing through or across the device. FIG. 10 includes a switch controller 300, a DC power input 305, a reactance control input 310, an electrically-controllable switching element S₁, a terminal T₁, a terminal T₂, a capacitor C₁, and a current pickup device 315. The switch controller 300 includes a DC power input 320, an RF pickup input 325, a duty cycle control input 330, and a switch control output 335. The electrically-controllable switching element S₁ may be any sort of electrically-controllable switching device, such as a MOSFET, a BJT, a pair of MOSFETs arranged as a bidirectional switch, etc. FIG. 10 shows an example embodiment of a variable capacitive reactance that can be placed in series with an LC resonator as shown in FIG. 1A, and FIG. 11 shows an example embodiment of a variable inductive reactance that can be placed in parallel with an LC resonator, as shown in FIG. 1B.

Note that, in some cases, it may be desirable to place multiple sets of parallel capacitors and switches or series inductors and switches in parallel, e.g., with all sets sharing the same two terminals and with all switches sharing a same switch control signal. This may be useful, for example, in cases where the active variable reactance is part of a resonator composed of conductors which are large compared to the physical sizes of the inductors, capacitors, and/or switches. Multiple inductors, capacitors, and/or switches may therefore be used such that the distribution of current through all of the parallel devices matches the intrinsic current distribution in the large conductor.

Similar to FIG. 10, FIG. 11 includes a switch controller 400, a DC power input 405, a reactance control input 410, an electrically-controllable switching element S₁, a terminal T₁, a terminal T₂, and an inductor L₁. The switch controller 400 includes a DC power input 420, a duty cycle control input 425, and a switch control output 430. The switch controller 400 may further include a positive RF pickup input 435 and a negative RF pickup input 440.

When the device shown in FIG. 10 is placed in series with an LC resonator, the LC resonator ensures that the RF current I_{RF} flowing from terminal T₁ to terminal T₂ is nearly sinusoidal. The current pickup component generates a voltage proportional to this RF current. This pickup may consist of a transformer, a series resistance or reactance, or any device which produces a signal proportional to the RF current flowing through the LC resonator to which the active variable reactance circuit is attached. The switch controller 300 may include a switch controller sub-circuit. In some examples, the switch controller 300 may take an RF Pickup sine wave as input and generate a square wave output with a variable duty cycle. The duty cycle may be controlled by the reactance control input 310. The phase of the square wave is chosen such that it leads I_{RF} by 90 degrees. In other words, the negative-slope zero-crossing of I_{RF} occurs at the mid-point of the time period where the square wave is in its low state.

The square wave output drives the switching element S₁. The switch is on when the square wave is in its high state, and off when the square wave is in its low state. When the device shown in FIG. 11 is placed in parallel with an LC resonator, the LC resonator ensures that the RF voltage V_{RF}, between terminal T₁ and terminal T₂, is nearly sinusoidal.

The switch controller sub-circuit takes the RF voltage V_{RF} as an input and generates a square wave output with a variable duty cycle. Note that, in general, the RF pickup need not necessarily come from the two terminals T₁ and T₂, but can come from any device attached to the LC resonator which produces a signal proportional to the RF voltage across the LC resonator to which the active variable reactance circuit is attached. The duty cycle is controlled by the reactance control input signal. The phase of the square wave is chosen such that it lags V_{RF} by 90 degrees. In other words, the negative-slope zero-crossing of V_{RF} occurs at the mid-point of the time period where the square wave is in its high state. The square wave output drives the switching element S₁. The switch is on when the square wave is in its high state, and off when the square wave is in its low state.

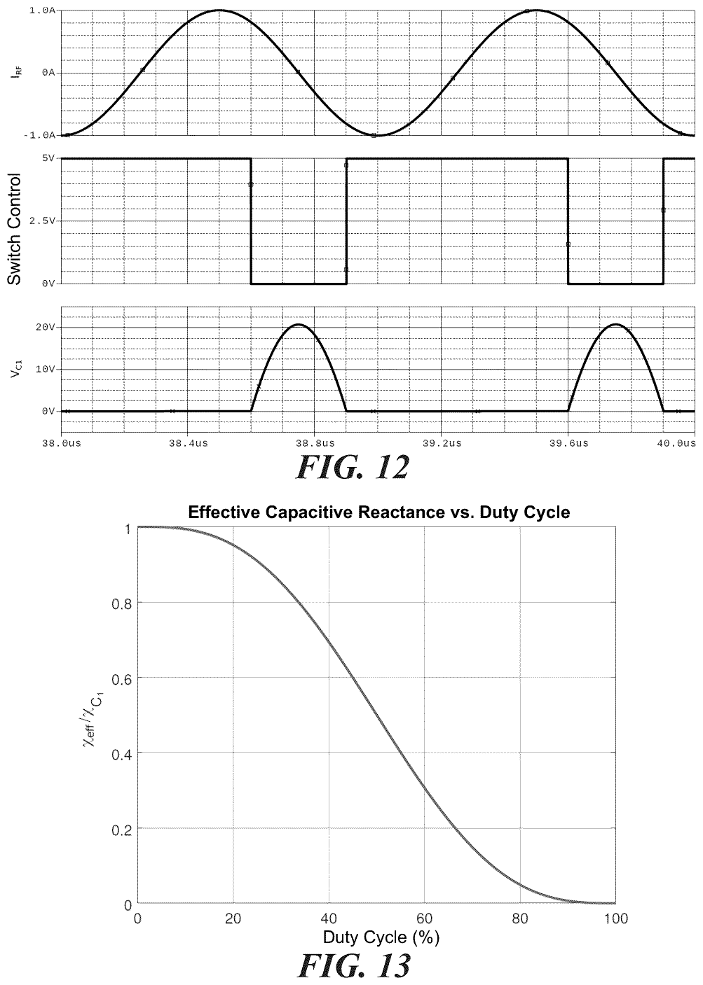

FIG. 12 illustrates how a variation of the duty cycle of the switch control square wave varies the effective capacitive reactance between terminals T₁ and T₂ in the circuit shown in FIG. 10. The sinusoidal current I_{RF} is shown in the top plot. The middle plot shows the switch control square wave. Note that the negative-slope zero-crossing of I_{RF} occurs at the midpoint of the low period of the switch control square wave. The bottom plot shows the voltage, V_{C1}, across capacitor, C₁. When the switch S₁ is on, V_{C1} is zero. When the switch is off, the current I_{RF} charges the capacitor C₁, causing its voltage to rise. The voltage reaches a peak when I_{RF} is zero. As I_{RF} becomes negative, V_{C1} begins to fall. When V_{C1} reaches zero, the switch turns on again. Note that the phase relation between I_{RF} and the switch control square wave guarantees that the switch turns on when V_{C1} is zero. This zero-voltage switching condition is necessary to ensure that the switch S₁ does not dissipate energy by discharging C₁ when it turns on.

During the time period when the switch is off, V_{C1}(t) is equal to a sine wave plus a DC offset. The amplitude of the sine wave component is equal to the amplitude of I_{RF} multiplied by the reactance of C₁. The full waveform V_{C1}(t) may be decomposed into a Fourier series. The LC resonator acts as a filter, and primarily responds to the Fourier component closest to its resonant frequency. Therefore, the behavior of the tunable LC resonator may be analyzed by examining only the fundamental component of this Fourier series. By dividing voltage amplitude of this fundamental component by the amplitude of I_{RF}, we arrive at the effective capacitive reactance, X_{eff}, as a function of the duty cycle δ:

$${X}_{e f f} = {X}_{{C}_{1}} ( \frac{sin ( 2 π δ )}{2 π} - δ + 1 ) , \qquad ( eq . 10 )$$

where X_{C}_{₁} is the reactance of capacitor C₁:

$${X}_{{C}_{1}} ≡ \frac{1}{ω {C}_{1}} , \qquad ( eq . 11 )$$

where ω is the angular frequency of the RF current, I_{RF}. The relation between the duty cycle and the effective capacitive reactance is plotted in FIG. 13. Note that by changing the duty cycle δ, the effective reactance may be continually varied over the range of 0 to X_{C}_{₁}.

We may define the effective capacitance, C_{VAR}, as follows:

$${C}_{V A R} ≡ \frac{1}{ω {X}_{e f f}} , \qquad ( eq . 12 )$$

Therefore, the effective variable capacitance is:

$${C}_{V A R} = \frac{{C}_{1}}{\frac{sin ( 2 π δ )}{2 π} δ + 1} . \qquad ( eq . 13 )$$

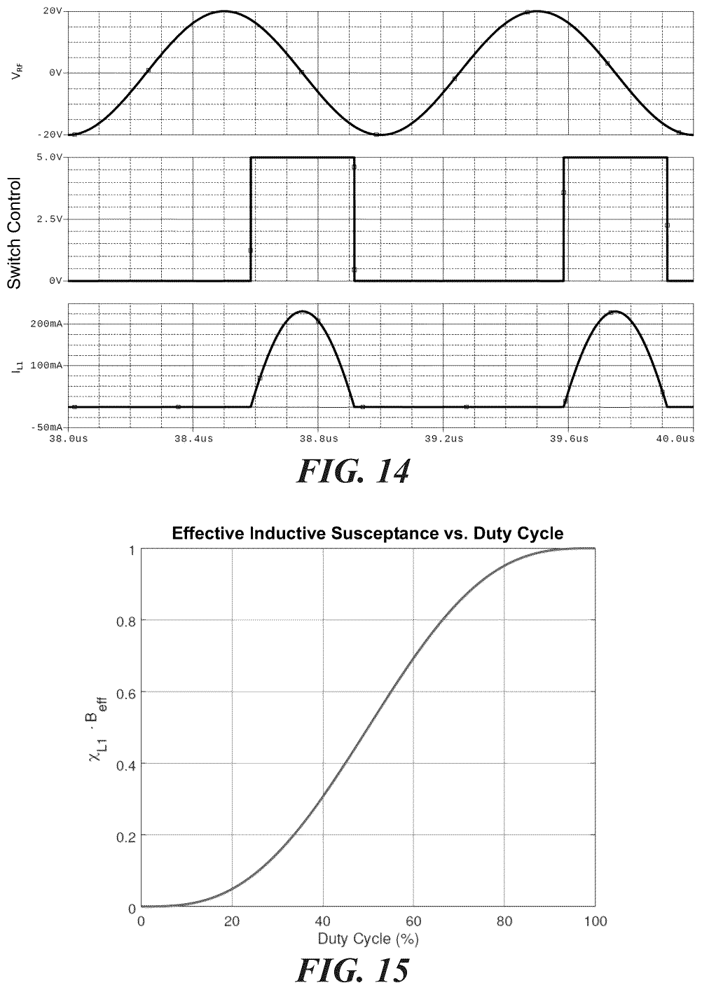

FIG. 14 illustrates how a variation of the duty cycle of the switch control square wave varies the effective inductive reactance between terminals T₁ and T₂ in the circuit shown in FIG. 11. The sinusoidal voltage, V_{RF}=V_{T}_{₁}−V_{T}_{₂}, is shown in the top plot. The middle plot shows the switch control square wave. Note that the negative-slope zero-crossing of V_{RF} occurs at the midpoint of the high period of the switch control square wave. The bottom plot shows the current I_{L1} through inductor L₁. When the switch S₁ is off, I_{L1} is zero. When the switch is on, the voltage V_{RF} causes the current in the inductor L₁ to increase. The current reaches a peak when V_{RF} is zero. As V_{RF} becomes negative, I_{L1} begins to fall. When I_{L1} reaches zero, the switch turns off again. Note that the phase relation between V_{RF} and the switch control square wave guarantees that the switch turns off when I_{L1} is zero. This zero-current switching condition is necessary to ensure that the switch S₁ does not dissipate energy from inductive kickback by turning off when I_{L1} not zero.

During the time period when the switch is on, I_{L1}(t) is equal to a sine wave plus a DC offset. The amplitude of the sine wave component is equal to the amplitude of V_{RF} divided by the reactance of L₁. The full waveform I_{L1}(t) may be decomposed into a Fourier series. The LC resonator acts as a filter, and primarily responds to the Fourier component closest to its resonant frequency. Therefore, the behavior of the tunable LC resonator may be analyzed by examining only the fundamental component of this Fourier series. By dividing the current amplitude of this fundamental component by the amplitude of V_{RF}, we arrive at the effective inductive susceptance, B_{eff}, as a function of the duty cycle δ:

$${B}_{e f f} = \frac{1}{{X}_{{L}_{1}}} ( δ - \frac{sin ( 2 π δ )}{2 π} ) , \qquad ( eq . 14 )$$

where X_{L1} is the reactance of inductor L₁:

$${X}_{{L}_{1}} ≡ ω {L}_{1} , \qquad ( eq . 15 )$$

where ω is the angular frequency of the RF voltage V_{RF}. The relation between the duty cycle and the effective inductive susceptance is plotted in FIG. 15. Note that by changing the duty cycle δ, the effective susceptance may be continually varied over the range of 0 to 1/X_{L}_{₁}.

The effective inductive reactance is equal to the reciprocal of the effective inductive susceptance:

$${X}_{e f f} = \frac{1}{{B}_{e f f}} = \frac{{X}_{{L}_{1}}}{δ - \frac{sin ( 2 πδ )}{δ}} . \qquad ( eq . 16 )$$

We may define the effective inductance, L_{VAR}, as follows:

$${L}_{V A R} ≡ \frac{{X}_{e f f}}{ω} . \qquad ( eq . 17 )$$

Therefore, the effective variable inductance is:

$${L}_{V A R} = \frac{{L}_{1}}{δ - \frac{sin ( 2 πδ )}{δ}} . \qquad ( eq . 18 )$$

Note that the sources of the RF Pickup shown in FIGS. 10 and 11 are merely one example of how the proper frequency and phase of the switch control square wave may be generated. In general, the RF Pickup can come from any source of RF in the LC resonator. For example, the RF Pickup may come from the RF voltage across an impedance in series with the LC resonator, or from the RF current though an admittance in parallel with the LC resonator, or from inductive or capacitive coupling to the LC resonator. Any of these methods may be used, so long as the proper phase relations are maintained between the switch control square wave and the voltages and currents in the LC resonator, namely, that the switch control square wave leads the current through terminals T₁ and T₂ by 90 degrees in the variable capacitive reactance circuit, and the switch control square wave lags the voltage across terminals T₁ and T₂ by 90 degrees in the variable inductive reactance circuit.

The switch control sub-circuits in the variable capacitive reactance and the variable inductive reactance circuits may require DC power in order to function. If the variable active reactance device is part of a system which has an external supply of power, the switch control sub-circuit may receive power from this external power source. However, in some cases, it is desirable for the LC resonator to be powered without any connection to an external DC power supply. For example, the LC resonator may be part of a resonant repeater which receives wireless power from a wireless power source and delivers it to a separate wireless power receiver. In such cases, it would be useful for the switch control sub-circuit to generate DC power from the RF power present in the LC resonator. This may be accomplished in a variety of ways, for example, by rectifying the RF voltage across a reactance in series with the LC resonator, rectifying the voltage across the LC resonator, or rectifying a voltage induced by inductive or capacitive coupling to the LC resonator.

In another example, the active variable reactance may be part of an actively powered LC resonator, but may be located in a position on the resonator where DC power cables cannot be routed without disrupting the tuning of that resonator. In such a case, the active variable reactance may be powered by rectifying the RF present in the LC resonator. Alternatively, the LC resonator may be arranged such that it is capable of supporting both RF and DC current simultaneously. This may be achieved by placing inductive chokes in parallel with capacitive junctions which need to pass DC current, or placing bypass capacitors in series with inductors in junctions which need a DC potential difference. In this way, DC power may be routed to the active variable reactance through the structure of the LC resonator itself, without requiring any additional wiring.

The Reactance Control Input allows the resonant frequency of an LC resonator to be electrically controlled when it incorporates either a capacitive or an inductive active variable reactance. This may be used as part of a feedback loop to regulate the RF current amplitude in the LC resonator when the LC resonator is placed in an external oscillating electric or magnetic field.

In some embodiments, this may be accomplished as follows. First, the tuning range should be chosen such that the resonant frequency of the LC resonator with the active variable reactance device is always greater than or always less than the driving frequency for all duty cycles. In other words, for a given driving frequency, the resonant frequency of the LC resonator does not pass through a point at which the resonant frequency equals the driving frequency at a certain duty cycle. Alternatively, the range of allowed duty cycles could be limited such that the duty cycle is only allowed to vary over a range in which the resonant frequency is always above or always below the driving frequency.

For a fixed driving amplitude and a fixed driving frequency, this guarantees a monotonic relationship between the duty cycle and the amplitude of the RF current in the LC resonator. Second, the amplitude of the RF current in the LC resonator may be compared to a desired set point. This comparison may be accomplished in a variety of ways, such as rectifying the RF voltage across the LC resonator or the RF voltage across an impedance in series with the LC resonator, and comparing the rectified DC voltage to a reference voltage. Third, a feedback circuit may be constructed which increases or decreases the duty cycle of the active variable reactance, i.e. varies the Reactance Control input, in order to reduce the error between the detected RF current amplitude in the LC resonator and the desired RF current amplitude in the LC resonator.

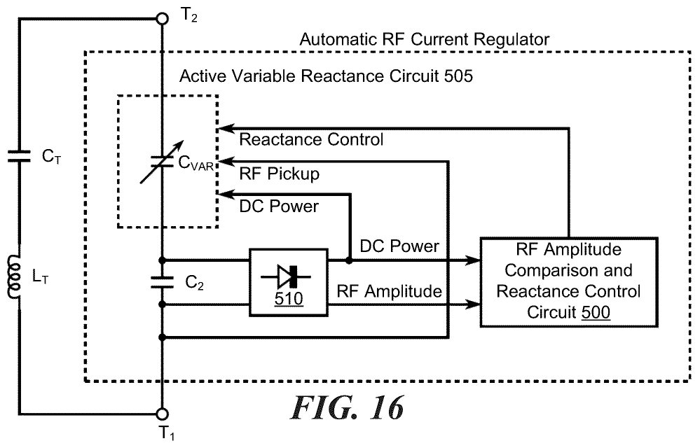

As an example of such a system, consider the block diagram shown in FIG. 16. The system consists of a series LC circuit, formed by L_{T} and C_{T}, connected to two terminals T₁ and T₂, of an Automatic RF Current Regulator circuit. The Automatic RF Current Regulator may include an active variable capacitance C_{VAR} in series with a second capacitance C2. The total series capacitance of the full system is given by:

$${C}_{s e r i e s} = \frac{1}{\frac{1}{{C}_{T}} + \frac{1}{{C}_{2}} + \frac{1}{{C}_{V A R}}} . \qquad ( eq . 19 )$$

The angular resonant frequency of the LC resonator is:

$${ω}_{r e s} = \frac{1}{\sqrt{{L}_{T} {C}_{s e r i e s}}} . \qquad ( eq . 20 )$$

If the resonator is driven by an external magnetic field oscillating at angular frequency, ω, the inductor, L_{T}, will experience an induced EMF V_{ind}. The total series reactance, Xₜₒₜ, of the system is:

$${X}_{tot} = ω {L}_{T} - \frac{1}{ω {C}_{T}} - \frac{1}{ω {C}_{2}} - \frac{1}{ω {C}_{V A R}} = {X}_{0} + {X}_{e f f} , \qquad ( eq . 21 )$$

where X₀ is a constant given by:

$${X}_{0} = ω {L}_{T} - \frac{1}{ω {C}_{T}} - \frac{1}{ω {C}_{2}} , \qquad ( eq . 22 )$$

and where X_{eff} is the effective series reactance of the variable active capacitance element:

$${X}_{e f f} = \frac{1}{ω {C}_{V A R}} = {X}_{{C}_{1}} ( \frac{sin ( 2 π δ )}{2 π} - δ + 1 ) \qquad ( eq . 23 )$$

where X_{C}_{₁} is the reactance of the switched capacitor, C₁, contained within the active variable capacitance element, and where δ is the duty cycle of the active variable capacitance element. Here, it will be assumed that X₀>0. This implies that Xₜₒₜ>0 for all values of δ. When the LC resonator has low loss, the RF current amplitude, |I_{RF}|, may be approximated as:

$$\vert {I}_{R F} \vert \approx \frac{{V}_{i n d}}{{X}_{t o t}} = \frac{{V}_{i n d}}{{X}_{0} + {X}_{eff}} . \qquad ( eq . 24 )$$

Therefore, we can see that the tuning condition, X₀>0, ensures that the RF current amplitude, |I_{RF}|, is a monotonic function of X_{eff}, which is a monotonic function of δ.

In the system shown in FIG. 16, a rectifier generates a DC signal which is proportional to the RF Current flowing through the LC resonator. This signal is compared to a set point by an RF amplitude comparison and reactance control circuit 500. The error between the RF amplitude signal to the internal set point is amplified and used to generate the reactance control signal, which is sent to an active variable reactance circuit 505. Because the RF amplitude DC signal is a monotonic function of the RF current amplitude, and the RF current amplitude is a monotonic function of the reactance control signal, an overall gain factor may be chosen for the full feedback loop such that the full loop has negative feedback. In general, the sign of this gain factor will depend on whether the monotonic functions have positive or negative slope.

Note also that, in addition to the RF amplitude output, a rectifier sub-circuit 510 provides a second DC Power output, which provides DC Power to the active variable reactance circuit 505 and the RF amplitude comparison and reactance control circuit 505. This DC power may be regulated such that its voltage is independent of the RF current amplitude of the LC resonator. Note also that the series capacitor C₂ provides a convenient source of RF voltage which is proportional to the RF current amplitude in the LC resonator. The voltage across capacitor C₂ is therefore used as the RF pickup input to the active variable reactance sub-circuit 505.

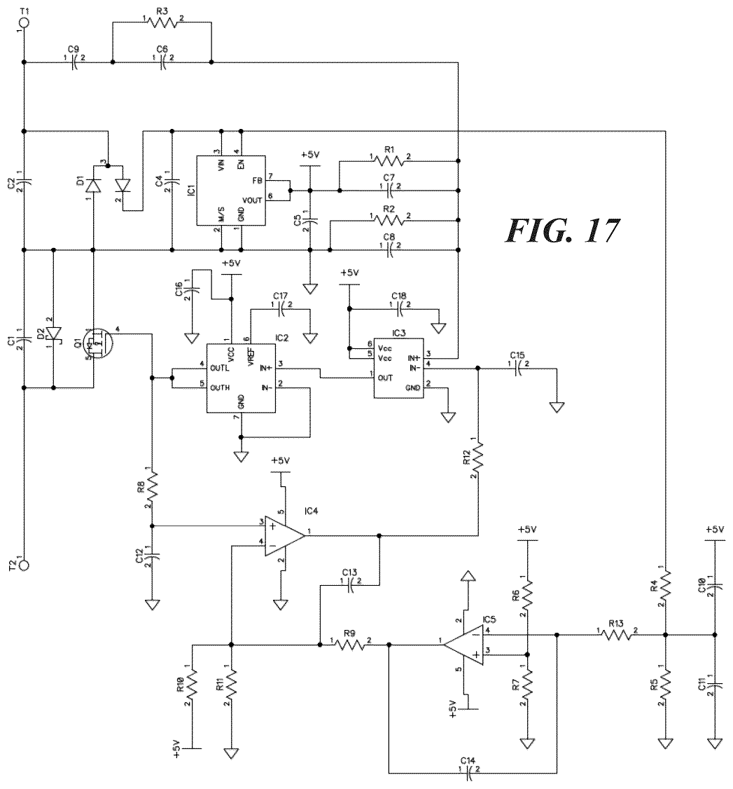

An example of an active variable reactance for automatic RF current regulation is shown in FIG. 17. The circuit may be a part of an LC resonator. A series inductance and capacitance is connected between terminals T₁ and T₂. This inductance and series capacitance, along with capacitors C₁ and C₂, form an LC resonator. An external RF power source induces a voltage in the inductance. The circuit rectifies the RF voltage across capacitor C₂ to provide a DC input to DC-to-DC converter IC₁. IC₁ provides 5 VDC to the rest of the circuit.

The RF sine wave on capacitor C₂ is filtered and fed into the input of comparator IC₃, which generates a square wave output. The duty cycle of the square wave is determined by the voltage on the inverting input of IC₃.

The square wave output of IC₃ goes to the gate driver IC₂, which drives the gate of MOSFET Q₁. Resistors R₁, R₂, and R₃, and capacitors C₆, C₇, and C₈, are chosen to shift the phase of the sine wave at the non-inverting input of IC₃ such that the square wave on the gate of Q₁ leads the RF current, I_{RF}, owing from terminal T₁ to terminal T₂ by 90 degrees. Note that the phase shift induced by R₁, R₂, R₃, C₆, C₇, and Cₛ may correct for a phase shift caused by propagation delay through IC₃ and IC₂.

MOSFET Q₁ may be in parallel with capacitor C₁. If MOSFET Q₁ is on all the time, those capacitors are shorted, and the effective reactance of those capacitors in series with the LC resonator is zero. If MOSFET Q₂ is off all the time, the full reactance of C₁ is placed in series with the LC resonator. If the duty cycle of MOSFET Q₁ is intermediate between κ% and 100%, the effective series reactance of C₁ will be between zero and its maximum value. Note that the diode D₂ is connected from the source to the drain of MOSFET Q₁. This diode is in parallel with the internal body diode of Q₁, and has the same polarity. It may be chosen to have a lower forward voltage drop than the body diode of Q₁, and therefore prevent conduction through the body diode of Q₁. This is beneficial in cases where the body diode of Q₁ has a reverse recovery time which is long compared to the period of the RF. In such a case, a diode D₂ may be chosen such that its reverse recovery time is much shorter than this period.

The diode D₂, ensures that the drain-to-source voltage of Q₁ never becomes more negative than the forward voltage drop of D₂. This ensures that no current is conducted through the body diode of Q₁ when Q₁ is off. The diode D₂ causes a DC charge to be present on capacitor C₁. Note that when the internal body diode of Q₁ has a sufficiently fast reverse recovery time, the diode D₂ may not be necessary. In such a case, the internal body diode of Q₁ plays the role of D₂. The duty cycle of Q₁ is set by a feedback loop involving Op-Amp IC₄. Resistor R₈ and capacitor C₁₂ filter the gate drive square wave and produce a DC voltage which is proportional to the duty cycle. This voltage is fed to the non-inverting input of IC₄. The output of IC₄ goes through a low-pass filter formed by R₁₂ and Cis to the inverting input of IC₃.

The voltage at the inverting input of IC₃ sets the duty cycle of its output square wave. The feedback loop involving IC₄ will change the duty cycle of that square wave until the voltage at the inverting input of IC₄ is equal to the voltage of the non-inverting input of IC₄. Therefore, the duty cycle of the gate-drive square wave will be equal to the DC voltage of the inverting input of IC₄ divided by 5 V.

The voltage of the inverting input of IC₄ is set by a second feedback loop involving Op-Amp IC₅. The output of IC₅ is connected to the inverting input of IC₄ through resistor R₉. The inverting input of IC₄ is also connected to its own output through capacitor C₁₃, to ground through R₁, and to +5 V through R₁₀. Because the output voltage of IC₅ is limited to be between 0 V and +5 V, resistors R₉, R₁₀, and Ru act as a voltage divider which sets an upper and a lower limit to the DC voltage at the inverting input of IC₄. These limits set the upper and lower limits of the duty cycle of the gate-drive square wave, respectively. The capacitor C₁₃, in conjunction with R₉, R₁₀, and R₁₁, acts as a low-pass filter. IC₅ compares the rectified voltage of C₄ to a pre-determined voltage set point, and adjusts its output voltage in order to maintain a constant rectified voltage on C₄. This works as follows.

An increase in the output voltage of IC₅ causes an increase in the duty cycle of the gate drive square wave. This causes Q₁ to be on for a greater fraction of the cycle, which reduces the effective reactance of capacitor C₁. The LC resonator is tuned so that its resonant frequency is higher than the driving frequency. Therefore, decreasing the series capacitive reactance will cause its resonant frequency to decrease. This brings it closer to resonating with the driving frequency, which causes the induced RF current amplitude to increase. This increases the RF voltage across capacitor C₂, which increases the rectified voltage across capacitor C₄. This voltage goes through the low-pass filter and voltage divider formed by R₄, R₅, C₁₀, and C₁₁. The filtered voltage goes to the inverting input of IC₅ through resistor R₁₃. Capacitor C₁₄ and resistor R₁₃ form an additional low-pass filter. As the DC voltage across capacitor C₄ goes up, so does the voltage at the inverting input of IC₅, which causes the output voltage of IC₅ to decrease, completing the negative feedback loop. Therefore, IC₅ maintains a constant RF voltage amplitude across capacitor C₂, which implies that it must maintain a constant RF current circulating in the LC resonator.

It should also be noted that the active variable reactances may be coupled to LC resonators in multiple ways. For example, if the LC resonator contains multiple capacitors or multiple inductors in series, an active variable reactance may be placed in parallel with one of these capacitors or inductors. Alternatively, if the LC resonator contains multiple inductors or multiple capacitors in parallel, the active variable reactance may be placed in series with one of these capacitors or inductors. Additionally, the active variable reactance may be inductively or capacitively coupled to the LC resonator.

Note that the LC resonators depicted in FIGS. 1A and 1B are the simplest reactive circuits which incorporate an active variable reactance. In general, the active variable reactance element may be placed in any circuit requiring variable reactance, so long as the circuit filters the voltage harmonics of the variable capacitance or the current harmonics of the variable inductance. An LC resonator naturally accomplishes this filtering, but other, more complex combinations of reactive components may accomplish this filtering as well.

For example, the active variable reactance may be incorporated into a T-filter or a π-filter, or some other more complex filter. Such a filter may be a low-pass, high-pass, band-pass filter, or band-stop filter. The active variable reactance could allow the cutoff frequency or frequencies of the filter to be electrically controlled. Alternatively, the active variable reactance may be used to electrically-control the input or output impedance of the filter in order to achieve electrically-controlled impedance matching.

Another example may be a resonator composed of multiple LC circuits, such as two adjacent LC resonator loops. Such a resonator may have multiple resonant modes. In a resonant wireless power system, the system of coupled resonators will be driven at one of its resonant modes. An active variable reactance can be coupled to one or more of the resonators in order to tune the desired resonant mode of operation such that its eigenfrequency is equal to the frequency of the driving source. Alternatively, the active variable reactance may be used to continuously change the tuning of one or more of the LC circuits in order to change the eigenmode structure of the entire coupled system. While keeping the driving frequency fixed, the system may be retuned such that a particular eigenmode becomes resonant with the driving frequency.

In this way, the relative phases and amplitudes of the voltages and currents throughout the LC structure may be chosen and set by one or more active variable reactances. Also note that one or more fixed inductive or capacitive reactances may be included in series or parallel with the switched reactive elements in the active variable reactance circuits 505. These additional components may be used to block DC voltage, block DC current, add or subtract additional reactance or susceptance, etc. The RF voltage across additional series components, or the current through additional parallel components, may also be used as a source of RF Pickup, or rectified as a source of DC Power. For example, FIG. 17 shows an example of an active variable capacitance which uses an additional capacitor placed in series with a switched capacitor C₁. The capacitor C₂ provides an RF voltage which is used both for RF Pickup and also rectified to provide DC Power.

Reactance Control Signal. In some cases, the active variable reactance circuit 505 may not share a ground with the control system which generates the Reactance Control input signal. It may also not share a ground with a source of DC power. In such cases, it would be desirable to provide a way of delivering the Reactance Control signal and/or DC power to the active variable reactance circuit 505 without directly connecting the grounds of the two circuits, which may cause an RF short, etc.

In such a case, the Reactance Control input could be provided to the active variable reactance circuit 505 through RF chokes, which pass the DC Reactance Control signal, but block RF. It could be provided through an optocoupler, which could be arranged to transfer analog or digital signals. If digital signals are transferred, then the active variable reactance circuit 505 could have an additional circuit which converts the digital signal into an analog signal which it may use for reactance control. Alternatively, the reactance control signal may also be communicated through fiber optics.

Another method for transferring the Reactance Control signal from the controller to the active variable reactance circuit 505 may be to transmit the signal wirelessly. This wireless transmission may be achieved using either analog or digital communications at a frequency which differs from the frequency of the RF power present in the LC resonator.

Another method may include using the superposition of DC and RF signals in the structure of the circuit to which the Active Variable Reactance is attached. If RF chokes or bypass capacitors are used to isolate the DC voltage across terminals T₁ and T₂ or the DC current through terminals T₁ and T₂ from the DC current through the internal inductor L₁, or the DC voltage across capacitor C₁, the DC voltage across T₁ and T₂ or DC current though T₁ and T₂ may controlled by an external source and may be used as the Reactance Control signal of the Active Variable Reactance.

If the Active Variable Reactance is also in need of a source of DC Power, then it may use coupling to, and rectification of, the RF power present in the LC resonator as its source of DC power. Alternatively, a DC voltage across T₁ and T₂ or a DC current through T₁ and T₂ may be used as a source of DC Power. For a certain range of DC voltages and/or currents, this externally-applied DC voltage and/or current may be used simultaneously as a source of DC Power and as a source of the Reactance Control signal.

Tuning of an LC Resonator Driven by an RF Generator. In some implementations of resonant wireless power, the source of the power will be an LC resonator driven by a Class-E RF generator which takes in external DC power and converts it to RF power in the LC resonator. This Class-E RF generator may be made to maintain high DC-to-RF efficiency by operating the switching element (typically a MOSFET) in a zero-voltage switching condition. This zero-voltage switching condition may be maintained by varying the duty cycle of the switching element in order to ensure that the switching element turns on at the time when its voltage reaches zero. A feedback system may be incorporated into the Class-E RF generator to adjust the duty cycle in order to maintain the RF generator in this condition.

Such a system is called Automatic Zero-Voltage Switching (AZVS), and it allows the Class-E amplifier to maintain high efficiency even when the LC resonator is detuned over a certain pre-defined range.

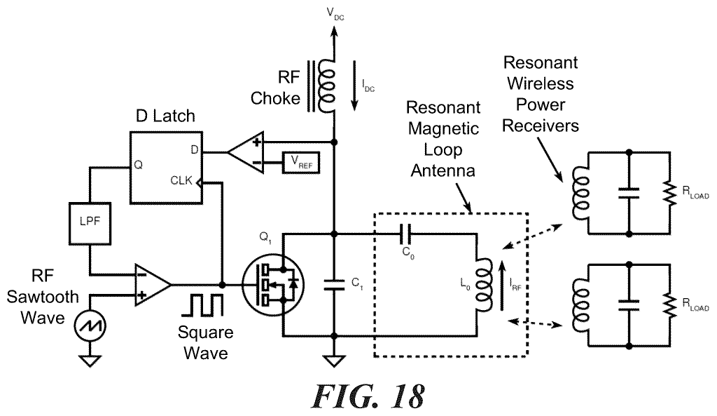

FIG. 18 shows an example of a Class-E RF generator with AZVS. The RF drive frequency, ƒ_{d}, is set by the frequency of the RF sawtooth wave input. A comparator converts the sawtooth wave to a square wave by comparing it to a DC voltage level. The square wave drives the gate of MOSFET Q₁. The drain and source of MOSFET Q₁ are in parallel with a capacitor C₁. The capacitor C₀ and the inductor L₀ form the LC tank circuit 10 of the Class-E RF generator. Let ƒ₀ denote the resonant frequency of the LC tank circuit 10, defined to be:

$${f}_{0} = \frac{1}{2 π \sqrt{{L}_{0} {C}_{0}}} . \qquad ( eq . 25 )$$

The inductor, L0, is a magnetic loop antenna which couples RF power to resonant wireless receivers. DC power is supplied to the circuit through an RF choke connected to the drain of Q1. The system may be characterized by a dimensionless constant, K, defined to be:

$$K ≡ \frac{{C}_{0}}{{C}_{0} + {C}_{1}} = \frac{{X}_{1}}{{X}_{1} + {X}_{0}} , \qquad ( eq . 26 )$$

and where X₀=1/(2πƒ_{d}C₀) and X₁=1/(2πƒ_{d}C₁) are the reactances of C₀ and C₁ respectively, at the drive frequency, ƒ_{d}.

A second comparator compares the drain voltage of Q1 to a reference voltage, V_{ref}, which is close to 0V. A D-latch latches the output of the comparator at the time of the rising edge of the gate-drive square wave. The output of the latch therefore indicates whether the drain voltage of Q1 is above or below V_{ref} at the instant when Q1 turns on. The output of the D-latch is low-pass filtered. If Q1 turns on too early, the output of the D-latch is high, causing the DC output of the low-pass filter to slowly rise, which shifts the rising edge of the gate-drive square wave later in the cycle. If Q1 turns on too late, the output of the D-latch is low, causing the DC output of the low-pass filter to slowly fall, which shifts the rising edge of the gate-drive square wave earlier in the cycle. Therefore, the AZVS feedback circuit controls the duty cycle of the gate-drive square wave such that the drain voltage of Q1 is equal to V_{ref} at the instant when Q1 turns on. If V_{ref} is set very close to 0 V, then the circuit will achieve Zero-Voltage Switching.

It is desirable to maintain a constant RF current in the LC resonator over a variety of both loading and tuning conditions. This constancy can allow receivers to be kept in a constant ambient field regardless of the loading of the loop. It also is desirable in order to prevent the Specific Absorption Rate in nearby human tissue from exceeding regulatory limits due to excursions of the RF current amplitude above the designed operating point.

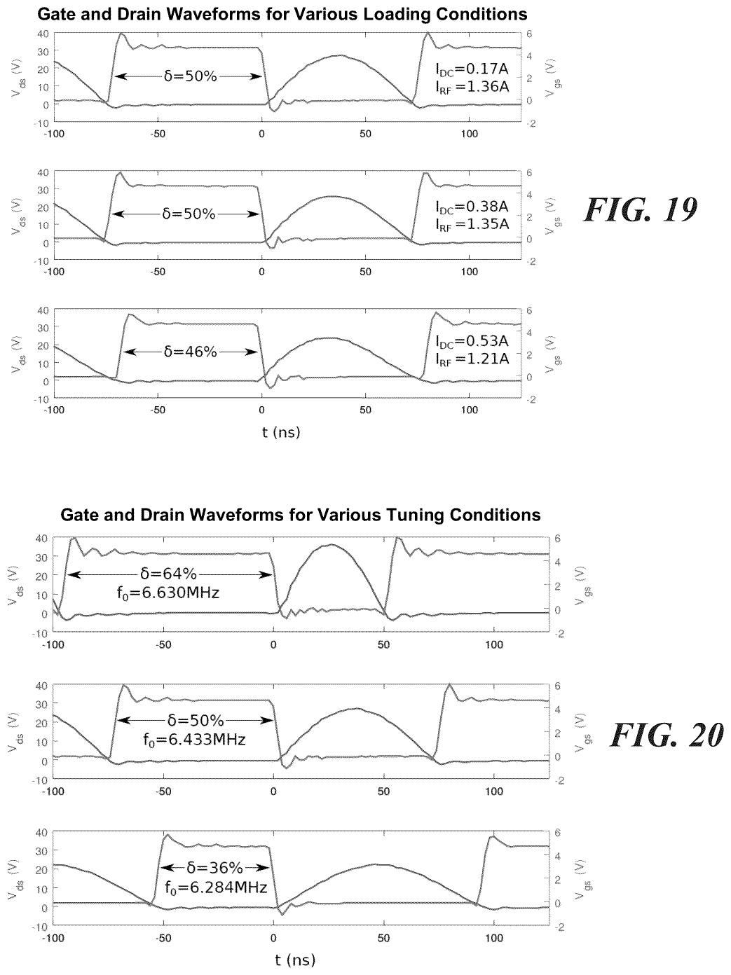

For a given tuning of ƒ₀, the AZVS Class-E RF generator will maintain an RF current amplitude in the LC resonator, which is substantially independent of the RF load, so long as the DC current remains much lower than the amplitude of the RF current in the LC resonator. This can be seen in FIG. 19.

However, when the resonator is detuned, the ratio of the RF current to the DC supply voltage changes. This can be seen in FIG. 20.

The tuning error of the LC resonator may be detected using the duty cycle of the AZVS Class-E RF generator. As long as the AZVS Class-E RF generator is operating under light loading conditions, the duty cycle will be a function primarily of the tuning of the LC resonator, and will have little dependence on the loading. The relation between the resonant frequency of the LC tank circuit ƒ₀ 10 and the AZVS duty cycle δ, is plotted in FIG. 14. Under light loading conditions, the relation between the resonant frequency ƒ₀ and the AZVS duty cycle δ, is given approximately by:

$$\frac{{f}_{0}}{{f}_{d}} \approx 1 - \frac{K}{2} ( 1 - δ + \frac{sin ( 2 π δ )}{2 π} ) . \qquad ( eq . 27 )$$

Equation 22 is a valid approximation when K<<1 and under light loading conditions, defined as I_{DC}<<I_{RF}, where I_{DC} and I_{RF} are the DC and RF currents of the Class-E amplifier (see FIG. 18).

Under light loading conditions (i.e., I_{DC}<<I_{RF}), the RF current amplitude is a function of the AZVS duty cycle δ.

$${I}_{R F} = \frac{π {V}_{D C}}{{X}_{S}} \cdot \frac{1}{sin ( π δ ) + π ( 1 - δ ) cos ( πδ )} , \qquad ( eq . 28 )$$

where X₁ is the reactance of capacitor C₁. The AZVS duty cycle is a function of ƒ₀. Therefore, the RF current amplitude will vary with ƒ₀. For this reason, it is desirable to detect this detuning of the LC resonator and correct it using an active variable reactance.

The difference between the actual duty cycle of the AZVS Class-E RF generator and a certain reference value can be used as an error signal in a feedback loop to control the tuning of the LC resonator. The tuning range of the LC resonator with the active variable reactance should be chosen such that the RF current amplitude of the LC resonator driven by the AZVS Class-E RF generator is a monotonic function of the Reactance Control Input.

The feedback loop can then change the tuning of the LC resonator in order to make the actual duty cycle equal to the reference value. Once the duty cycle is fixed, the ratio of the RF current to the DC supply voltage will be fixed. This will keep the RF current amplitude substantially constant over a range of both tuning and loading conditions.

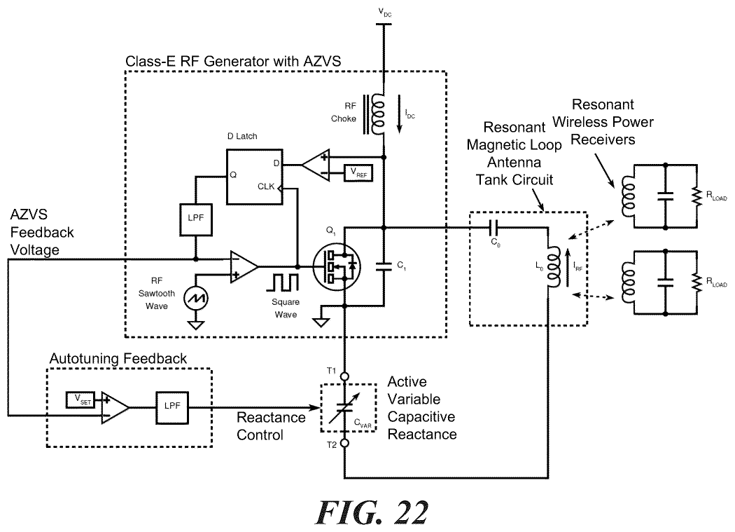

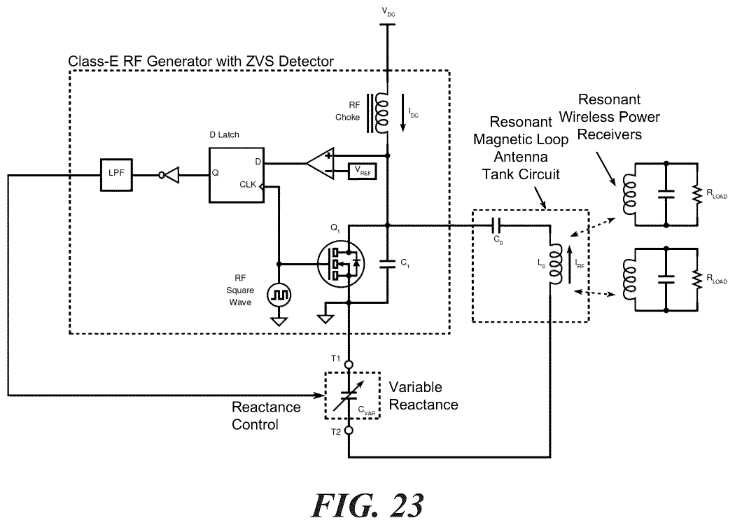

FIG. 22 shows an example of how the autotuning may work. A Class-E RF Generator with AZVS is connected to an LC tank circuit 10 comprising a capacitor C0 and an inductor L0 in series with an active variable capacitive reactance. In this example, the Active Variable Capacitive Reactance gets its DC power from the same source as the Class-E RF Generator with AZVS. The resonant frequency of the tank circuit ƒ₀ is given by:

$${f}_{0} = \frac{1}{2 π \sqrt{{L}_{0} {C}_{s e r i e s}}} , \qquad ( eq . 29 )$$

where the total series capacitance is given by the relation:

$$\frac{1}{{C}_{s e r i e s}} = \frac{1}{{C}_{0}} + \frac{1}{{C}_{V A R}} , \qquad ( eq . 30 )$$

where C_{VAR} is the effective capacitance of the Active Variable Capacitive Reactance circuit.

The feedback loop works as follows. The effective capacitance, C_{VAR}, of the Active Variable Capacitive Reactance increases monotonically with an increase in its Reactance Control input. The series capacitance, Cₛₑᵣᵢₑₛ, increases monotonically with an increase in C_{VAR}. The resonant frequency ƒ₀ decreases monotonically with an increase in Cₛₑᵣᵢₑₛ.

The duty cycle of the Class-E RF Generator with AZVS decreases monotonically with a decrease in ƒ₀. The AZVS Feedback Voltage is proportional to 1−δ. Therefore, the AZVS Feedback Voltage increases monotonically as decreases. The output of the Autotuning Feedback sub-circuit decreases monotonically as the AZVS Feedback Voltage increases. The output of the Autotuning Feedback sub-circuit is sent to the Reactance Control input of the Active Variable Capacitive Reactance, which completes the negative feedback loop.

The Autotuning Feedback sub-circuit compares the AZVS Feedback Voltage to a fixed voltage, VSET, and high DC gain of the negative feedback loop works to ensure that the AZVS Feedback Voltage is equal to VSET in equilibrium. Note that the circuit contains two feedback loops, one internal to the Class-E RF Generator with AZVS, as well as a larger loop which controls the tuning of the LC tank circuit 10. The cutoff frequency of the low-pass filter in the AZVS feedback loop should be chosen to be higher than the cutoff frequency of the low-pass filter in the Autotuning Feedback sub-circuit. This will ensure that the AZVS is always in an approximately steady-state condition relative to the time scale of the Autotuning Feedback system.

The circuit shown in FIG. 22 will automatically adjust the tuning of the LC tank circuit 10 in order to keep the duty cycle δ of the Class-E RF Generator with AZVS fixed.

The duty cycle set point will be set by the voltage, VSET. As shown by FIGS. 13 and 12, the AZVS duty cycle is mainly a function of the resonant frequency ƒ₀ and substantially independent of the load. Therefore, by fixing the AZVS duty cycle δ the tank circuit resonant frequency ƒ₀ will also be fixed.

The autotuning will therefore make the system largely insensitive to variations in component values, or environmental perturbations which affect the inductance of L0. The system will therefore maintain a constant RF current amplitude in the LC tank circuit 10 under a variety of both tuning and loading conditions.

Note that it is also possible to eliminate the internal feedback loop in the Class-E RF Generator with AZVS, such that the MOSFET Q₁ is driven at a constant duty cycle. Instead of changing the duty cycle to maintain the ZVS condition, the Active Variable Capacitive Reactance may be used instead to vary the tuning of the LC tank circuit 10 until the ZVS condition is satisfied.

FIG. 23 shows an example of how this may be achieved. A comparator and D-latch detect whether the drain voltage of Q₁ is above or below V_{REF} when Q₁ turns on. If the drain voltage of Q₁ is above V_{REF} when Q₁ switches on, the output of the D-latch will be high. This output goes through an inverter and a low-pass filter. If the output of the D-latch is high, the output of the inverter will be low, and the output of the low-pass filter will slowly fall, decreasing the Reactance Control input of the Variable Reactance.

As the Reactance Control input falls, the resonant frequency of the LC tank circuit 10 will rise, which will cause the drain voltage of Q₁ at the instant it turns on to decrease. This completes the feedback loop.

In the examples described in this section, the switching devices used were MOSFETs. However, any general switching device would work, so long as its switching speed is fast compared to the driving frequency. The LC tank circuit 10 was also tuned using an active variable capacitive reactance. However, any general active variable reactance, or combination of active variable reactances may be used, such as active variable inductances, or combinations of active variable inductances and capacitances.

Note that, in general, the active variable capacitive reactance shown in FIG. 22 and the variable reactance shown in FIG. 23 may be any kind of electrically-controllable variable reactances.

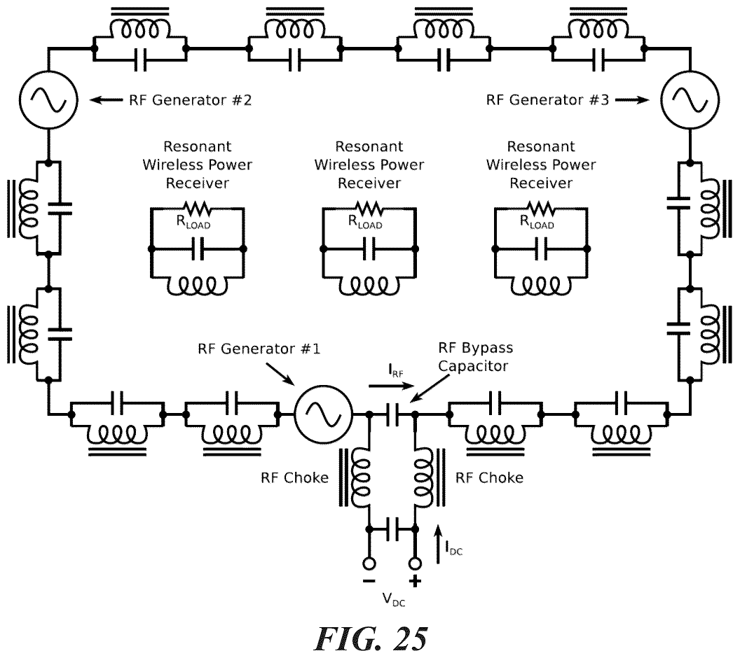

Tuning of a LC Resonator Driven by Distributed AZVS Class-E RF Generators. In some cases, it is desirable to drive a resonant magnetic loop antenna from multiple RF generators distributed in series around the loop. FIG. 25 shows an example of a loop with three distributed RF generators. The series capacitors in the loop are modified with the addition of parallel RF chokes, which allow DC current to bypass the capacitors. This allows a DC current to circulate around the loop in addition to the RF current, which enables the RF generators to take in DC power from the same two terminals which they use to output RF power.

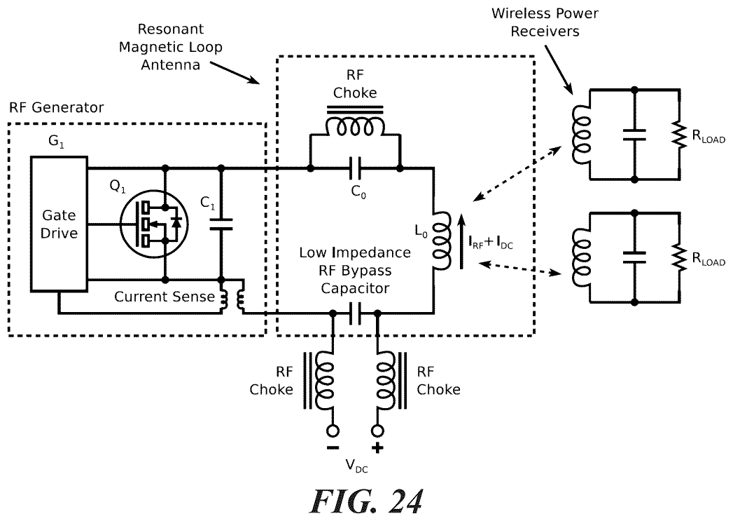

FIG. 24 shows an example of how a Class-E RF generator may be modified so that it takes in DC power from the same two terminals that it uses to output RF power. It is also important that all RF generators be phase-locked, and FIG. 24 also illustrates an example of how this may be achieved. The RF generator contains a current-sensing transformer which picks up a signal proportional to the RF current circulating in the magnetic loop antenna. The gate-drive circuit generates a square wave which is phase-locked to this signal. Because all distributed RF generators are in series and share the same RF current, this phase-locking mechanism will guarantee that they will all have the same phase relative to each other.

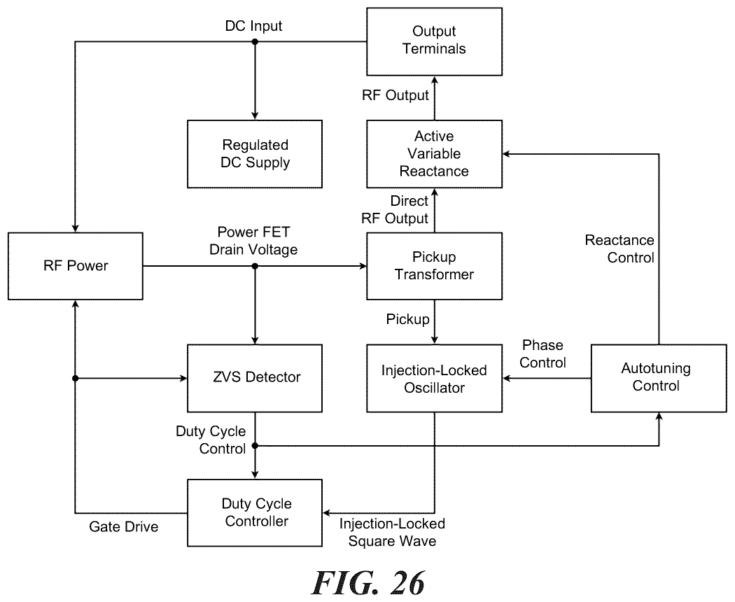

As in the case of a magnetic loop antenna driven by a single RF generator, it may be desirable in some cases to use active variable reactance to tune the magnetic loop antenna driven by multiple, distributed RF generators. FIG. 26 shows how this may be accomplished through a modification of the RF generators. Specifically, FIG. 26 depicts a block diagram for a single RF generator for use in a distributed RF generator system with autotuning. As before, the output terminals serve a dual purpose: as an RF output and as a DC input. The DC input power goes to the RF Power sub-circuit and the Regulated DC Supply, which supplies a stable DC voltage to the rest of the circuit.

The RF Power sub-circuit contains a switching element, such as a MOSFET, which takes in a Gate Drive signal from the Duty Cycle Controller sub-circuit. RF power from the Power FET Drain Voltage is output through a Pickup Transformer, in series with an Active Variable Reactance, and sent to the Output Terminals.

The Power FET Drain Voltage is sensed by a ZVS Detector at the rising edge of the Gate Drive signal to detect if the Power FET Drain Voltage is above or below a certain Reference Voltage at the instant when the Power FET is switched on. This may be achieved using a D-latch and comparator, as shown in FIG. 18, for example. The Duty Cycle Control output of the ZVS Detector slowly rises with time if the rising edge of the Gate Drive signal occurs while the Power FET Drain Voltage is above the Reference Voltage.

The Duty Cycle Control output of the ZVS Detector slowly falls with time if the rising edge of the Gate Drive signal occurs while the Power FET Drain voltage is below the Reference Voltage. The characteristic timescale for the rising or falling of the Duty Cycle Control output is determined by the cutoff frequency of a low-pass filter inside the ZVS Detector sub-circuit.

The Duty Cycle Control output of the ZVS Detector goes to the Duty Cycle Controller sub-circuit. This sub-circuit takes in an Injection-Locked Square Wave, and outputs a Gate Drive square wave which has a duty cycle that monotonically decreases as the Duty Cycle Control signal increases. Note that the sign of the logic, and the sign of analog control signals, may be inverted without changing the overall behavior of the circuit, so long as the signs of the inputs and outputs of the sub-circuits to which those control signals connect are all inverted consistently.

The RF Power sub-circuit, ZVS Detector sub-circuit, and Duty Cycle Controller sub-circuit form a closed feedback loop which automatically adjusts the duty cycle of the Gate Drive square wave such that the RF Power sub-circuit always operates in a state of Zero-Voltage Switching.

The Injection-Locked Square Wave is output from an Injection-Locked Oscillator sub-circuit, which takes a sine-wave Pickup input from the secondary of a Pickup Transformer. The Injection-Locked Oscillator sub-circuit generates a square wave at the intended frequency of operation of the system, plus or minus a certain frequency tolerance. When a signal is present at the Pickup input, the Injection-Locked Oscillator locks its frequency to that of the Pickup input. There will be a small phase difference between the phase of the Injection-Locked Square Wave and the phase of the Pickup input, which will be proportional to the difference in frequency between signal present at the Pickup input and the natural frequency of the Injection-Locked Oscillator.

The primary of the Pickup Transformer is in series with the magnetic loop antenna in which the RF Generator is placed. Therefore, the Pickup signal is proportional to the RF current circulating in the magnetic loop antenna, which is shared by all of the series-connected RF Generators. By locking the frequency of the Injection-Locked Square Wave to the frequency of the RF current circulating in the magnetic loop antenna, all of the RF Generators are locked in frequency relative to each other. Each RF Generator will have a small phase difference relative to the average phase of all the distributed RF Generators due to the difference between the natural frequency of its Injection-Locked Oscillator and the average natural frequency of all the Injection-Locked Oscillators.

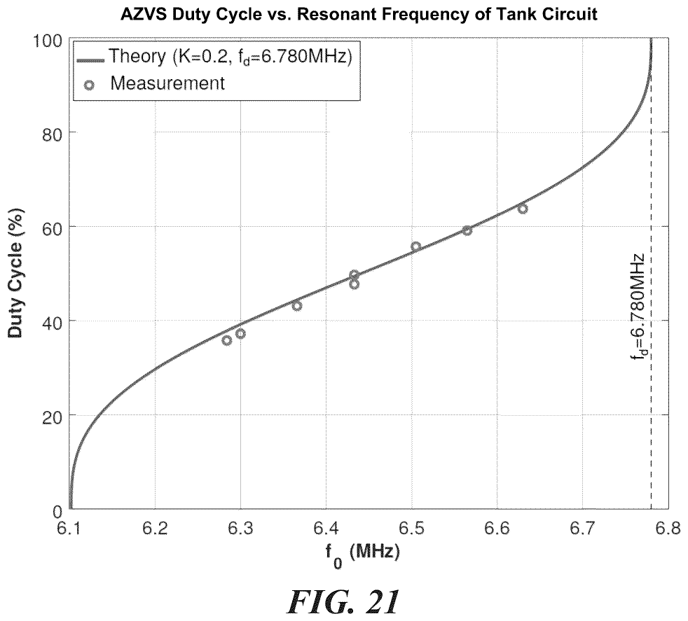

The phase differences between the RF Generators may be reduced by imposing tighter tolerances on the natural frequencies of the Injection-Locked Oscillators. When the AZVS feedback system has reached a steady state each RF Generator will have a duty cycle which depends on the overall tuning of the magnetic loop antenna. See FIG. 21 for an example of this relation for a single, Class-E RF generator. Therefore, the Duty Cycle Control signal in each RF Generator circuit may be used as a local measurement of the detuning of the entire loop, and the difference between the Duty Cycle Control signal and a desired set-point may be used as an error signal to control an Active Variable Reactance which will alter the tuning of the magnetic loop antenna.

It is often the case that the magnetic loop antenna may need to be tuned over a certain fractional tuning range, Δƒ₀/ƒ_{d}, which is independent of the size of the loop, where ƒ₀ is the range of resonant frequencies over which the loop must be tuned, and ƒ_{d} is the driving frequency of the loop. The resonant frequency of the magnetic loop antenna is:

$${f}_{0} = \frac{1}{2 π \sqrt{{L}_{0} {C}_{0}}} , \qquad ( eq . 31 )$$

where L₀ and C₀ are the total series inductance and capacitance of the magnetic loop antenna, respectively. The relation between Δƒ₀, ΔL₀, and ΔC₀ is:

$$\frac{Δ {f}_{0}}{{f}_{0}} \approx - \frac{1}{2} \frac{Δ {L}_{0}}{{L}_{0}} - \frac{1}{2} \frac{Δ {C}_{0}}{{C}_{0}} \approx - \frac{1}{2} \frac{Δ {X}_{{L}_{0}}}{{X}_{{L}_{0}}} + \frac{1}{2} \frac{Δ {X}_{{C}_{0}}}{{X}_{{C}_{0}}} , \qquad ( eq . 32 )$$

where X_{L}_{₀}=2πƒ_{d}L₀, and X_{C}_{₀}=1/(2πƒ_{d}C₀). The errors in the capacitive and inductive reactances of the magnetic loop antenna may be due to component tolerances or due to environmental effects. In either case, the fractional error will likely be independent of the size of the loop. Therefore, the absolute error of these reactances will grow with the size of the loop.

It is therefore desirable to add an active variable reactance in series with the loop which can be tuned to correct for these errors. However, the size of this correction factor grows with the size of the loop. It may therefore become impractical to use a single active variable reactance to retune the loop when the loop size is large.

A natural solution to this problem is to add an Active Variable Reactance to every RF generator, as shown in the block diagram in FIG. 26. Because the number of distributed RF Generators grows as the loop size grows, so too will the number of Active Variable Reactances in series with the loop. The total series reactance of all the Active Variable Reactances will therefore grow with the size of the loop, allowing a nearly constant fractional tuning range to be achieved for loops of varying size.

Because the Duty Cycle Control signal may be used in each RF Generator circuit as a local measurement of the detuning of the entire loop, it may be used to control an Active Variable Reactance sub-circuit within each RF Generator. The Autotuning Control sub-circuit forms a feedback loop which outputs a Reactance Control signal proportional to the difference between the Duty Cycle Control signal and a pre-defined duty cycle set-point. The gain of this feedback loop can be chosen such that it exhibits negative feedback. A low-pass filter should be added to this feedback loop, within the Autotuning Control sub-circuit, such that the AZVS feedback loop has time to stabilize in a steady state on a timescale much faster than the timescale of the autotuning feedback loop.

Note that the Autotuning Control sub-circuit should not have infinite gain at DC, since, as described above, there will be variations between all of the RF Generators which will cause them all to have small phase shifts relative to each other. Therefore, when the while magnetic loop antenna is tuned such that the average duty cycle of all of the RF Generators is equal to the desired duty cycle set point, each individual RF Generator will have a small phase shift which will cause its duty cycle to differ from the set-point by a small amount. If this difference was amplified with infinite gain by the Autotuning Control sub-circuit, the Active Variable Reactance sub-circuit would be saturated at either its highest or lowest reactance. The magnitude of the gain in the Autotuning Control sub-circuit should therefore be chosen such that the scale of the duty cycle error, multiplied by the gain factor, gives a Reactance Control output signal which is still within the range of values for which the Active Variable Reactance sub-circuit is responsive.

The phase error between RF Generator circuits may be corrected using a third feedback loop, which is designed to operate on a timescale slower than both the autotuning feedback loop and the AZVS feedback loop. When the autotuning feedback loop is in a steady state, the remaining difference between the Duty Cycle Control signal and the desired set-point will produce an error signal proportional to the phase error of that RF Generator, which is proportional to the error in its natural frequency. This error may be corrected using a Phase Control signal which is input to the Injection-Locked Oscillator sub-circuit. This Phase Control signal may be used to adjust the natural frequency and/or phase of the Injection-Locked Oscillator sub-circuit, and may be arranged to produce negative feedback, such that the difference between the Duty Cycle Control signal and the desired set point is driven toward zero.

This third feedback loop is optional, and may not be needed if the error in the natural frequencies of the Injection-Locked Oscillators are sufficiently small. However, it may be useful for making the system more tolerant of frequency errors in the Injection-Locked Oscillators, which may allow the use of less expensive components with larger tolerances.

While the disclosure has been described with respect to a limited number of embodiments, those skilled in the art, having benefit of this disclosure, will appreciate that other embodiments can be devised which do not depart from the scope of the disclosure as disclosed herein. Accordingly, the scope of the disclosure should be limited only by the attached claims.

The features, structures, or characteristics described above may be combined in one or more embodiments in any suitable manner, and the features discussed in the various embodiments are interchangeable, if possible. In the following description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims.

The terms “first,” “second,” “third,” etc. in the description or claims are used only as labels, rather than a limitation for a number of the objects unless specified otherwise. It is understood that if multiple components are shown, the components may be referred to in the claims as a “first” component, a “second” component, a “third” component, and so forth, to the extent applicable.

The above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

Clause 1. A system, comprising: an active variable reactance circuit configured to control a resonant frequency of at least one resonant circuit, comprising: an electrically-controllable switching element; a passive reactive component connected to at least one terminal of the electrically-controllable switching element; and a switch controller sub-circuit configured to switch the electrically-controllable switching element at a frequency of a radio-frequency (RF) current or voltage passing through or across a device.

Clause 2. The system of clause 1, wherein the electrically-controllable switching element is one of: a metal-oxide-semiconductor field-effect transistor (MOSFET), a bipolar junction transistor (BJT), and a pair of MOSFETs arranged as a bidirectional switch.

Clause 3. The system of any of clauses 1-2, wherein: the passive reactive component provides a variable capacitive reactance that is in series with the at least one resonant circuit; or the passive reactive component provides a variable inductive reactance that is in parallel with the at least one resonant circuit.

Clause 4. The system of any of clauses 1-3, further comprising a current pickup device configured to generate a voltage proportional to the RF current and provide the voltage to the switch controller sub-circuit.

Clause 5. The system of any of clauses 1-4, wherein the current pickup device is one of: a transformer, a series resistance device, and a series reactance device.

Clause 6. The system of any of clause 1-5, wherein the switch controller sub-circuit is configured to receive an RF pickup signal in a form of a sine wave from the current pickup device as an input, and generate a square wave output signal having a variable duty cycle, the square wave output signal driving the electrically-controllable switching element.

Clause 7. The system of any of clauses 1-6, wherein the variable duty cycle is controlled by a reactance control input signal provided to the switch controller sub-circuit.

Clause 8. The system of any of clauses 1-7, wherein a phase of the square wave output signal leads the RF current by 90 degrees.

Clause 9. The system of any of clauses 1-8, wherein the at least one resonant circuit is a part of a resonant repeater that receives wireless power from a wireless power source and delivers power to a separate wireless power receiver.

Clause 10. The system of any of clauses 1-9, further comprising an automatic RF current regulator circuit configured to: identify a DC signal generated by the at least one resonant circuit that is proportional to the RF current flowing through the at least one resonant circuit; compare the DC signal to an internal set point using an RF amplitude comparison and reactance control circuit; and amplify an error between the RF amplitude signal the internal set point and transmit the error as amplified as a reactance control signal to an active variable reactance sub-circuit.

Clause 11. The system of any of clauses 1-10, further comprising the at least one resonant circuit.

Clause 12. The system of any of clauses 1-11, wherein the electrically-controllable switching element is a single electrically-controllable switching element of the active variable reactance circuit.

Clause 13. A system, comprising: an active variable reactance circuit configured to control a resonant frequency of at least one resonant circuit, comprising: an electrically-controllable switching element in parallel with at least one capacitor; and a switch controller sub-circuit configured to switch the electrically-controllable switching element at a frequency of a radio-frequency (RF) current or voltage passing through or across a device such that the RF current flowing from a first terminal to a second terminal is substantially sinusoidal.

Clause 14. A system, comprising: an active variable reactance circuit configured to control a resonant frequency of at least one resonant circuit, comprising: an electrically-controllable switching element in series with at least one inductor; and a switch controller sub-circuit configured to switch the electrically-controllable switching element at a frequency of a radio-frequency (RF) current or voltage passing through or across a device such that the RF voltage across a first terminal and a second terminal is substantially sinusoidal.

Clause 15. A method, comprising: controlling, by an active variable reactance circuit, a resonant frequency of at least one resonant circuit by: providing an electrically-controllable switching element; providing a passive reactive component connected to at least one terminal of the electrically-controllable switching element; and switching, by a switch controller sub-circuit, the electrically-controllable switching element at a frequency of a radio-frequency (RF) current or voltage passing through or across a device.

Clause 16. The method of clause 15, wherein the electrically-controllable switching element is one of: a metal-oxide-semiconductor field-effect transistor (MOSFET), a bipolar junction transistor (BJT), and a pair of MOSFETs arranged as a bidirectional switch.

Clause 17. The method of any of clauses 15-16, wherein: the switch controller provides a variable capacitive reactance that is in series with the resonant circuit; or the switch controller provides a variable inductive reactance that is in parallel with the resonant circuit.

Clause 18. The method of any of clauses 15-17, further comprising generating, by a current pickup device, a voltage proportional to the RF current and providing the voltage to the switch controller sub-circuit.

Clause 19. The method of any of clauses 15-18, wherein the current pickup device is one of: a transformer, a series resistance device, and a series reactance device.

Clause 20. The method of any of clauses 15-19, further comprising: receiving, by the switch controller sub-circuit, an RF pickup signal in a form of a sine wave from the current pickup device as an input; and generating, by the switch controller sub-circuit, a square wave output signal having a variable duty cycle, the square wave output signal; driving the electrically-controllable switching element using the square wave output signal.

Clause 21. The method of any of clauses 15-20, wherein the variable duty cycle is controlled by a reactance control input signal provided to the switch controller sub-circuit.

Clause 22. The method of any of clauses 15-21, wherein a phase of the square wave output signal leads the RF current by 90 degrees.

Clause 23. The method of any of clauses 15-22, wherein the at least one resonant circuit is a part of a resonant repeater that receives wireless power from a wireless power source and delivers power to a separate wireless power receiver.

Clause 24. The method of any of clauses 15-23, further comprising, using an automatic RF current regulator circuit: identifying a DC signal generated by the at least one resonant circuit that is proportional to the RF current flowing through the at least one resonant circuit; comparing the DC signal to an internal set point using an RF amplitude comparison and reactance control circuit; amplifying an error between the RF amplitude signal the internal set point; and transmitting the error as amplified as a reactance control signal to an active variable reactance sub-circuit.

Therefore, the following is claimed:

1. A system, comprising:
an active variable reactance circuit configured to control a resonant frequency of at least one resonant circuit, comprising:
an electrically-controllable switching element;
a passive reactive component connected to at least one terminal of the electrically-controllable switching element; and
a switch controller sub-circuit configured to switch the electrically-controllable switching element at a frequency of a radio-frequency (RF) current or voltage passing through or across a device.

2. The system of claim 1, wherein the electrically-controllable switching element is one of: a metal-oxide-semiconductor field-effect transistor (MOSFET), a bipolar junction transistor (BJT), and a pair of MOSFETs arranged as a bidirectional switch.

3. The system of claim 1, wherein:
the passive reactive component provides a variable capacitive reactance that is in series with the at least one resonant circuit; or
the passive reactive component provides a variable inductive reactance that is in parallel with the at least one resonant circuit.

4. The system of claim 1, further comprising a current pickup device configured to generate a voltage proportional to the RF current and provide the voltage to the switch controller sub-circuit.

5. The system of claim 4, wherein the current pickup device is one of: a transformer, a series resistance device, and a series reactance device.

6. The system of claim 4, wherein the switch controller sub-circuit is configured to receive an RF pickup signal in a form of a sine wave from the current pickup device as an input, and generate a square wave output signal having a variable duty cycle, the square wave output signal driving the electrically-controllable switching element.

7. The system of claim 6, wherein the variable duty cycle is controlled by a reactance control input signal provided to the switch controller sub-circuit.

8. The system of claim 6 or 7, wherein a phase of the square wave output signal leads the RF current by 90 degrees.

9. The system of claim 1, wherein the at least one resonant circuit is a part of a resonant repeater that receives wireless power from a wireless power source and delivers power to a separate wireless power receiver.

10. The system of claim 1, further comprising an automatic RF current regulator circuit configured to:
identify a DC signal generated by the at least one resonant circuit that is proportional to the RF current flowing through the at least one resonant circuit;
compare the DC signal to an internal set point using an RF amplitude comparison and reactance control circuit; and
amplify an error between the RF amplitude signal the internal set point and transmit the error as amplified as a reactance control signal to an active variable reactance sub-circuit.

11. The system of claim 1, further comprising the at least one resonant circuit.

12. The system of claim 1, wherein the electrically-controllable switching element is a single electrically-controllable switching element of the active variable reactance circuit.

13. A method, comprising:
controlling, by an active variable reactance circuit, a resonant frequency of at least one resonant circuit by:
providing an electrically-controllable switching element;
providing a passive reactive component connected to at least one terminal of the electrically-controllable switching element; and
switching, by a switch controller sub-circuit, the electrically-controllable switching element at a frequency of a radio-frequency (RF) current or voltage passing through or across a device.

14. The method of claim 13, wherein the electrically-controllable switching element is one of: a metal-oxide-semiconductor field-effect transistor (MOSFET), a bipolar junction transistor (BJT), and a pair of MOSFETs arranged as a bidirectional switch.

15. The method of claim 13, wherein:
the switch controller provides a variable capacitive reactance that is in series with the resonant circuit; or
the switch controller provides a variable inductive reactance that is in parallel with the resonant circuit.

16. The method of claim 13, further comprising generating, by a current pickup device, a voltage proportional to the RF current and providing the voltage to the switch controller sub-circuit.

17. The method of claim 16, wherein the current pickup device is one of: a transformer, a series resistance device, and a series reactance device.

18. The method of claim 16, further comprising:
receiving, by the switch controller sub-circuit, an RF pickup signal in a form of a sine wave from the current pickup device as an input; and
generating, by the switch controller sub-circuit, a square wave output signal having a variable duty cycle, the square wave output signal;
driving the electrically-controllable switching element using the square wave output signal.

19. The method of claim 18, wherein the variable duty cycle is controlled by a reactance control input signal provided to the switch controller sub-circuit.

20. The method of claim 18, wherein a phase of the square wave output signal leads the RF current by 90 degrees.
